(19) United States
(12) Patent Application Publication
(10) Pub. No.: US 2026/0134828 A1
(43) Pub. Date: May 14, 2026

(54) ARRAY SUBSTRATE AND DISPLAY APPARATUS

(71) Applicants: Chengdu BOE Optoelectronics Technology Co., Ltd., Chengdu, Sichuan (CN); BOE Technology Group Co., Ltd., Beijing (CN); Beijing BOE Technology Development Co., Ltd., Beijing (CN)

(72) Inventors: Feifei Gao, Beijing (CN); Yao Huang, Beijing (CN); Tingliang Liu, Beijing (CN); Lang Liu, Beijing (CN)

(73) Assignees: Chengdu BOE Optoelectronics Technology Co., Ltd., Chengdu, Sichuan (CN); BOE Technology Group Co., Ltd., Beijing (CN); Beijing BOE Technology Development Co., Ltd., Beijing (CN)

(21) Appl. No.: 18/697,191

(22) PCT Filed: May 30, 2023
(86) PCT No.: PCT/CN2023/096999

§ 371 Date: Mar. 29, 2024

(51) Int. Cl. G09G 3/3233; H10K 59/121; H10K 59/126; H10K 59/131

(52) U.S. Cl. CPC G09G 3/3233; H10K 59/1213; H10K 59/1216; H10K 59/126; H10K 59/131; G09G 2300/0408; G09G 2300/0426; G09G 2300/0819; G09G 2310/08

(57) ABSTRACT

An array substrate is provided. The array substrate includes a plurality of pixel driving circuits. A respective pixel driving circuit of the plurality of pixel driving circuits comprises a driving transistor, a light shield, and a node connecting line. An orthographic projection of the light shield on a base substrate substantially covers an orthographic projection of an active layer of the driving transistor on the base substrate. The light shield is electrically connected to a gate electrode of the driving transistor through the node connecting line. The light shield, the node connecting line, and the gate electrode of the driving transistor are in three different layers.

### TECHNICAL FIELD

The present invention relates to display technology, more particularly, to an array substrate and a display apparatus.

### BACKGROUND

Organic Light Emitting Diode (OLED) display is one of the hotspots in the field of flat panel display research today. Unlike Thin Film Transistor-Liquid Crystal Display (TFT-LCD), which uses a stable voltage to control brightness, OLED is driven by a driving current required to be kept constant to control illumination. The OLED display panel includes a plurality of pixel units configured with pixel-driving circuits arranged in multiple rows and columns. Each pixel-driving circuit includes a driving transistor having a gate terminal connected to one gate line per row and a drain terminal connected to one data line per column. When the row in which the pixel unit is gated is turned on, the switching transistor connected to the driving transistor is turned on, and the data voltage is applied from the data line to the driving transistor via the switching transistor, so that the driving transistor outputs a current corresponding to the data voltage to an OLED device. The OLED device is driven to emit light of a corresponding brightness.

### SUMMARY

In one aspect, the present disclosure provides an array substrate, comprising a plurality of pixel driving circuits; wherein a respective pixel driving circuit of the plurality of pixel driving circuits comprises a driving transistor, a light shield, and a node connecting line; wherein an orthographic projection of the light shield on a base substrate substantially covers an orthographic projection of an active layer of the driving transistor on the base substrate; the light shield is electrically connected to a gate electrode of the driving transistor through the node connecting line; the light shield, the node connecting line, and the gate electrode of the driving transistor are in three different layers.

Optionally, the respective pixel driving circuit further comprises a first reset transistor; wherein the light shield is electrically connected to a second electrode of the first reset transistor through the node connecting line.

Optionally, the respective pixel driving circuit further comprises a storage capacitor; wherein the orthographic projection of the light shield on the base substrate substantially covers an orthographic projection of a gate electrode of the driving transistor on the base substrate, and substantially covers an orthographic projection of a second capacitor electrode of the storage capacitor on the base substrate.

Optionally, the array substrate further comprises a plurality of third voltage supply lines; wherein the respective pixel driving circuit further comprises a light emitting control transistor, and a second reset transistor; an orthographic projection of a respective third voltage supply line of the plurality of third voltage supply lines on the base substrate substantially covers an orthographic projection of an active layer of the light emitting control transistor in the respective pixel driving circuit on the base substrate, substantially covers an orthographic projection of an active layer of the second reset transistor on the base substrate, and at least partially overlaps with the orthographic projection of the active layer of the driving transistor on the base substrate.

Optionally, the orthographic projection of a respective third voltage supply line of the plurality of third voltage supply lines on the base substrate substantially covers an orthographic projection of a combination of an active layer, a first electrode, and a second electrode of the light emitting control transistor in the respective pixel driving circuit on the base substrate; substantially covers an orthographic projection of a combination of an active layer, a first electrode, and a second electrode of the second reset transistor on the base substrate; substantially covers an orthographic projection of a combination of a first electrode and a second electrode of the driving transistor on the base substrate; and at least partially overlaps with an orthographic projection of an active layer of the driving transistor on the base substrate.

Optionally, the array substrate further comprises a plurality of fourth voltage supply lines; wherein the respective pixel driving circuit further comprises a data write transistor and a first reset transistor; in a first column of pixel driving circuits, an orthographic projection of a respective fourth voltage supply line of the plurality of fourth voltage supply lines on the base substrate substantially covers an orthographic projection of an active layer of the first reset transistor in a first respective pixel driving circuit in the first column of pixel driving circuits on the base substrate, and substantially covers an orthographic projection of an active layer of the data write transistor in the first respective pixel driving circuit in the first column of pixel driving circuits on the base substrate.

Optionally, in the first column of pixel driving circuits, the orthographic projection of a respective fourth voltage supply line of the plurality of fourth voltage supply lines on the base substrate substantially covers an orthographic projection of a combination of an active layer, a first electrode, and a second electrode of the first reset transistor in the first respective pixel driving circuit in the first column of pixel driving circuits on the base substrate, and substantially covers an orthographic projection of a combination of an active layer and a second electrode of the data write transistor in the first respective pixel driving circuit in the first column of pixel driving circuits on the base substrate.

Optionally, the array substrate further comprises a plurality of fourth reset signal lines; wherein the respective pixel driving circuit further comprises a data write transistor and a first reset transistor; in a second column of pixel driving circuits, an orthographic projection of a respective fourth reset signal line of the plurality of fourth reset signal lines on the base substrate substantially covers an orthographic projection of an active layer of the first reset transistor in a second respective pixel driving circuit in the second column of pixel driving circuits on the base substrate, and substantially covers an orthographic projection of an active layer of the data write transistor in the second respective pixel driving circuit in the second column of pixel driving circuits on the base substrate.

Optionally, in the second column of pixel driving circuits, the orthographic projection of a respective fourth reset signal line of the plurality of fourth reset signal lines on the base substrate substantially covers an orthographic projection of a combination of an active layer, a first electrode, and a second electrode of the first reset transistor in the second respective pixel driving circuit in the second column of pixel driving circuits on the base substrate; and substantially covers an orthographic projection of a combination of an active layer and a second electrode of the data write transistor in the second respective pixel driving circuit in the second column of pixel driving circuits on the base substrate.

Optionally, the array substrate further comprises a plurality of third reset signal lines; wherein the respective pixel driving circuit further comprises a data write transistor and a first reset transistor; in a third column of pixel driving circuits, an orthographic projection of a respective third reset signal line of the plurality of third reset signal lines on the base substrate substantially covers an orthographic projection of an active layer of the first reset transistor in a third respective pixel driving circuit in the third column of pixel driving circuits on the base substrate, and substantially covers an orthographic projection of an active layer of the data write transistor in the third respective pixel driving circuit in the third column of pixel driving circuits on the base substrate.

Optionally, in the third column of pixel driving circuits, the orthographic projection of a respective third reset signal line of the plurality of third reset signal lines on the base substrate substantially covers an orthographic projection of a combination of an active layer, a first electrode, and a second electrode of the first reset transistor in the third respective pixel driving circuit in the third column of pixel driving circuits on the base substrate; and substantially covers an orthographic projection of a combination of an active layer and a second electrode of the data write transistor in the third respective pixel driving circuit in the third column of pixel driving circuits on the base substrate.

Optionally, the array substrate further comprises a plurality of fourth voltage supply lines; wherein the respective pixel driving circuit further comprises a data write transistor and a first reset transistor; pixel driving circuits of the array substrate are arranged in columns, including a (3k-2)-th column, a (3k-1)-th column, and a (3k)-th column of K columns, K and k being positive integers, 1≤k≤(K/3); in the (3k-2)-th column of pixel driving circuits, an orthographic projection of a respective fourth voltage supply line of the plurality of fourth voltage supply lines on the base substrate substantially covers an orthographic projection of an active layer of the first reset transistor in a first respective pixel driving circuit in the (3k-2)-th column of pixel driving circuits on the base substrate, and substantially covers an orthographic projection of an active layer of the data write transistor in the first respective pixel driving circuit in the (3k-2)-th column of pixel driving circuits on the base substrate.

Optionally, the array substrate further comprises a plurality of fourth reset signal lines; wherein the respective pixel driving circuit further comprises a data write transistor and a first reset transistor; pixel driving circuits of the array substrate are arranged in columns, including a (3k-2)-th column, a (3k-1)-th column, and a (3k)-th column of K columns, K and k being positive integers, 1≤k≤(K/3); in the (3k-1)-th column of pixel driving circuits, an orthographic projection of a respective fourth reset signal line of the plurality of fourth reset signal lines on the base substrate substantially covers an orthographic projection of an active layer of the first reset transistor in a second respective pixel driving circuit in the (3k-1)-th column of pixel driving circuits on the base substrate, and substantially covers an orthographic projection of an active layer of the data write transistor in the second respective pixel driving circuit in the (3k-1)-th column of pixel driving circuits on the base substrate.

Optionally, the array substrate further comprises a plurality of third reset signal lines; wherein the respective pixel driving circuit further comprises a data write transistor and a first reset transistor; pixel driving circuits of the array substrate are arranged in columns, including a (3k-2)-th column, a (3k-1)-th column, and a (3k)-th column of K columns, K and k being positive integers, 1≤k≤(K/3); in the (3k)-th column of pixel driving circuits, an orthographic projection of a respective third reset signal line of the plurality of third reset signal lines on the base substrate substantially covers an orthographic projection of an active layer of the first reset transistor in a third respective pixel driving circuit in the (3k)-th column of pixel driving circuits on the base substrate, and substantially covers an orthographic projection of an active layer of the data write transistor in the third respective pixel driving circuit in the (3k)-th column of pixel driving circuits on the base substrate.

Optionally, the array substrate further comprises a plurality of fourth voltage supply lines, a plurality of fourth reset signal lines, and a plurality of third reset signal lines in a same layer;

wherein pixel driving circuits of the array substrate are arranged in columns, including a (3k-2)-th column, a (3k-1)-th column, and a (3k)-th column of K columns, K and k being positive integers, 1≤k≤(K/3); the (3k-2)-th column comprises a fourth voltage supply line of the plurality of fourth voltage supply lines; the (3k-1)-th column comprises a fourth reset signal line of the plurality of fourth reset signal lines; and the (3k)-th column comprises a third reset signal line of the plurality of third reset signal lines.

Optionally, the plurality of fourth voltage supply lines are absent in the (3k-1)-th column and absent in the (3k)-th column; the plurality of fourth reset signal lines are absent in the (3k-2)-th column and absent in the (3k)-th column; and the plurality of third reset signal lines are absent in the (3k-2)-th column and absent in the (3k-1)-th column.

Optionally, the array substrate further comprises a first voltage supply network and a second voltage supply network; wherein the first voltage supply network comprises a plurality of first voltage supply lines and a plurality of third voltage supply lines interconnected to each other; the plurality of first voltage supply lines extend along a direction substantially parallel to a first direction; the plurality of third voltage supply lines extend along a direction substantially parallel to a second direction; a respective first voltage supply line of the plurality of first voltage supply lines is connected to one or more third voltage supply lines of the plurality of third voltage supply lines; a respective third voltage supply line of the plurality of third voltage supply lines is connected to one or more first voltage supply lines of the plurality of first voltage supply lines; and wherein the second voltage supply network comprises a plurality of second voltage supply lines and a plurality of fourth voltage supply lines interconnected to each other; the plurality of second voltage supply lines extend along a direction substantially parallel to the first direction; the plurality of fourth voltage supply lines extend along a direction substantially parallel to the second direction; a respective second voltage supply line of the plurality of second voltage supply lines is connected to one or more fourth voltage supply lines of the plurality of fourth voltage supply lines; and a respective fourth voltage supply line of the plurality of fourth voltage supply lines is connected to one or more second voltage supply lines of the plurality of second voltage supply lines; wherein pixel driving circuits of the array substrate are arranged in columns, including a (3k-2)-th column, a (3k-1)-th column, and a (3k)-th column of K columns, K and k being positive integers, 1≤k≤(K/3); the plurality of third voltage supply lines are present in the (3k-2)-th column, present in the (3k-1)-th column, and present in the (3k)-th column; the plurality of fourth voltage supply lines are absent in the (3k-1)-th column and absent in the (3k)-th column.

Optionally, the array substrate further comprises a first reset signal network; wherein the first reset signal network comprises a plurality of first reset signal lines and a plurality of third reset signal lines interconnected to each other; the plurality of first reset signal lines extend along a direction substantially parallel to a first direction; the plurality of third reset signal lines extend along a direction substantially parallel to a second direction, a respective first reset signal line of the plurality of first reset signal lines is connected to one or more third reset signal lines of the plurality of third reset signal lines; and a respective third reset signal line of the plurality of third reset signal lines is connected to one or more first reset signal lines of the plurality of first reset signal lines; wherein pixel driving circuits of the array substrate are arranged in columns, including a (3k-2)-th column, a (3k-1)-th column, and a (3k)-th column of K columns, K and k being positive integers, 1≤k≤(K/3); and the plurality of third reset signal lines are absent in the (3k-2)-th column and absent in the (3k-1)-th column.

Optionally, the array substrate further comprises a second reset signal network; wherein the second reset signal network comprises a plurality of second reset signal lines and a plurality of fourth reset signal lines interconnected to each other; the plurality of second reset signal lines extend along a direction substantially parallel to a first direction; the plurality of fourth reset signal lines extend along a direction substantially parallel to a second direction; a respective second reset signal line of the plurality of second reset signal lines is connected to one or more fourth reset signal lines of the plurality of fourth reset signal lines; and a respective fourth reset signal line of the plurality of fourth reset signal lines is connected to one or more second reset signal lines of the plurality of second reset signal lines; wherein pixel driving circuits of the array substrate are arranged in columns, including a (3k-2)-th column, a (3k-1)-th column, and a (3k)-th column of K columns, K and k being positive integers, 1≤k≤(K/3); and the plurality of fourth reset signal lines are absent in the (3k-2)-th column and absent in the (3k)-th column.

In another aspect, the present disclosure provides a display apparatus, comprising the array substrate described herein, and one or more integrated circuits connected to the array substrate.

### BRIEF DESCRIPTION OF THE FIGURES

The following drawings are merely examples for illustrative purposes according to various disclosed embodiments and are not intended to limit the scope of the present invention.

FIG. 1 is a plan view of an array substrate in some embodiments according to the present disclosure.

FIG. 2A is a circuit diagram illustrating the structure of a pixel driving circuit in some embodiments according to the present disclosure.

FIG. 2B is a timing diagram illustrating the operation of a pixel driving circuit in some embodiments according to the present disclosure.

FIG. 3A is a diagram illustrating the structure of a portion of an array substrate in some embodiments according to the present disclosure.

FIG. 3B is a schematic diagram illustrating an arrangement of a plurality of pixel driving circuits in a portion of an array substrate depicted in FIG. 3A.

FIG. 3C is a diagram illustrating the structure of a light shield layer in the portion of the array substrate depicted in FIG. 3A.

FIG. 3D is a diagram illustrating the structure of a first conductive layer in the portion of the array substrate depicted in FIG. 3A.

FIG. 3E is a diagram illustrating the structure of a first gate insulating layer in the portion of the array substrate depicted in FIG. 3A.

FIG. 3F is a diagram illustrating the structure of a semiconductor material layer in the portion of the array substrate depicted in FIG. 3A.

FIG. 3G is a diagram illustrating the structure of a second conductive layer in the portion of the array substrate depicted in FIG. 3A.

FIG. 3H is a diagram illustrating the structure of a passivation layer in the portion of the array substrate depicted in FIG. 3A.

FIG. 3I is a diagram illustrating the structure of a first signal line layer in the portion of the array substrate depicted in FIG. 3A.

FIG. 3J is a diagram illustrating the structure of a first planarization layer in the portion of the array substrate depicted in FIG. 3A.

FIG. 3K is a diagram illustrating the structure of a second signal line layer in the portion of the array substrate depicted in FIG. 3A.

FIG. 3L is a diagram illustrating the structure of a second planarization layer in the portion of the array substrate depicted in FIG. 3A.

FIG. 4A is a cross-sectional view along an A-A+ line in FIG. 3A.

FIG. 4B is a cross-sectional view along a B-B′ line in FIG. 3A.

FIG. 5 is a diagram illustrating the structure of a first voltage supply network in a portion of an array substrate in some embodiments according to the present disclosure.

FIG. 6 is a diagram illustrating the structure of a second voltage supply network in a portion of an array substrate in some embodiments according to the present disclosure.

FIG. 7 is a diagram illustrating the structure of a first reset signal network in a portion of an array substrate in some embodiments according to the present disclosure.

FIG. 8 is a diagram illustrating the structure of a second reset signal network in a portion of an array substrate in some embodiments according to the present disclosure.

FIG. 9 is a diagram illustrating the structure of a semiconductor material layer and a second signal line layer in the portion of the array substrate depicted in FIG. 3A.

### DETAILED DESCRIPTION

The disclosure will now be described more specifically with reference to the following embodiments. It is to be noted that the following descriptions of some embodiments are presented herein for purpose of illustration and description only. It is not intended to be exhaustive or to be limited to the precise form disclosed.

The present disclosure provides, inter alia, an array substrate and a display apparatus that substantially obviate one or more of the problems due to limitations and disadvantages of the related art. In one aspect, the present disclosure provides an array substrate. In some embodiments, the array substrate includes a plurality of pixel driving circuits. Optionally, a respective pixel driving circuit of the plurality of pixel driving circuits comprises a driving transistor, a light shield, and a node connecting line. Optionally, an orthographic projection of the light shield on a base substrate substantially covers an orthographic projection of an active layer of the driving transistor on the base substrate. Optionally, the light shield is electrically connected to a gate electrode of the driving transistor through the node connecting line. Optionally, the light shield, the node connecting line, and the gate electrode of the driving. transistor are in three different layers.

Various appropriate pixel driving circuits may be used in the present array substrate. Examples of appropriate driving circuits include 3T1C, 2T1C, 4T1C, 4T2C, 5T2C, 6T1C, 7T1C, 7T2C, 8T1C, and 8T2C. In some embodiments, the respective one of the plurality of pixel driving circuits is a 5T1C driving circuit. In alternative embodiments, the respective one of the plurality of pixel driving circuits is a 5T2C driving circuit. Various appropriate light emitting elements may be used in the present array substrate. Examples of appropriate light emitting elements include organic light emitting diodes, quantum dots light emitting diodes, and micro light emitting diodes. Optionally, the light emitting element is micro light emitting diode. Optionally, the light emitting element is an organic light emitting diode including an organic light emitting layer.

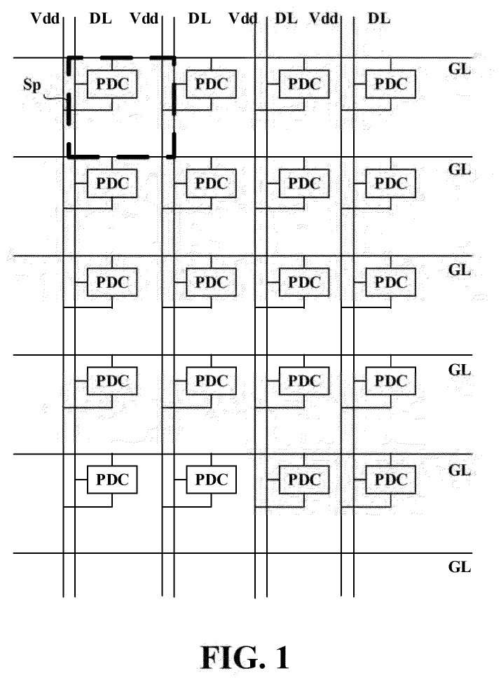

FIG. 1 is a plan view of an army substrate in some embodiments according to the present disclosure. Referring to FIG. 1, the array substrate includes an array of subpixels Sp. Each subpixel includes an electronic component, e.g., a light emitting element. In one example, the light emitting element is driven by a respective pixel driving circuit PDC. The array substrate includes a plurality of gate lines GL, a plurality of data lines DL, a plurality of voltage supply lines Vdd (e.g., a plurality of first voltage supply lines or a plurality of third voltage supply lines). Light emission in a respective subpixel Sp is driven by a respective pixel driving circuit PDC. In one example, a high voltage signal (e.g., a VDD signal) is input, through a respective voltage supply line of the plurality of voltage supply line Vdd, to the respective pixel driving circuit PDC connected to an anode of the light emitting element: a low voltage signal (e.g., a VSS signal) is input, through a low voltage supply line, to a cathode of the light emitting element. A voltage difference between the high voltage signal (e.g., the VDD signal) and the low voltage signal (e.g., the VSS signal) is a driving voltage AV that drives light emission in the light emitting element.

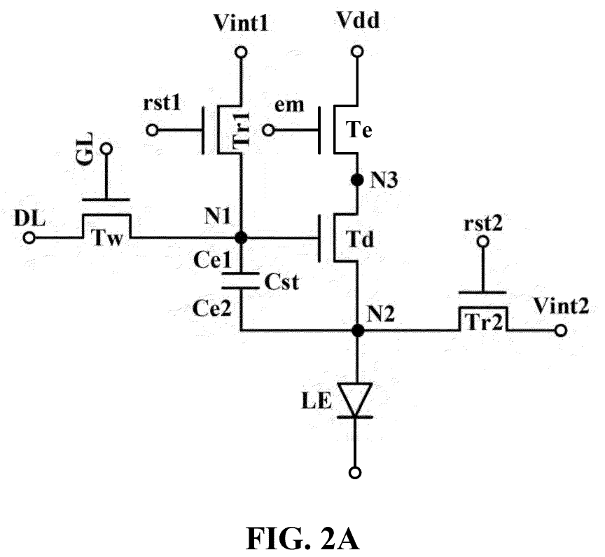

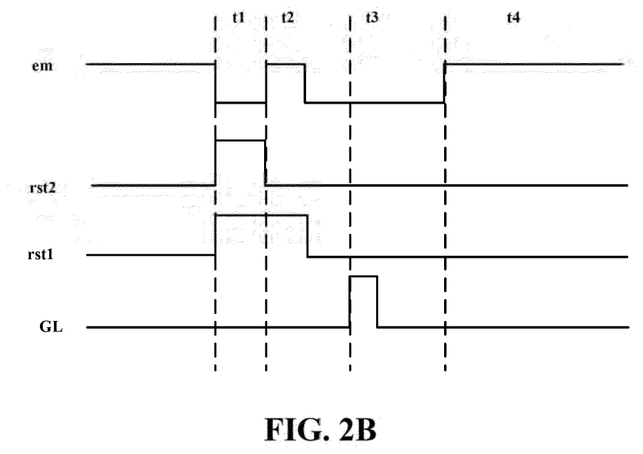

FIG. 2A is a circuit diagram illustrating the structure of a pixel driving circuit in some embodiments according to the present disclosure. Referring to FIG. 2A, in some embodiments, the pixel driving circuit includes a driving transistor Td; a storage capacitor Cst having a first capacitor electrode Ce1 and a second capacitor electrode Ce2; a data write transistor Tw having a gate electrode connected to a respective gate line of a plurality of gate lines GL, a first electrode connected to a respective data line of a plurality of data lines DL, and a second electrode connected to a gate electrode of the driving transistor Td; a first reset transistor Tr1 having a gate electrode connected to a respective first reset control signal line of a plurality of first reset control signal lines rst1, a first electrode connected to a respective first reset signal line of a plurality of first reset signal lines Vint1, and a second electrode connected to a first capacitor electrode Ce1 of the storage capacitor Cst, the second electrode of the data write transistor Tw, and the gate electrode of the driving transistor Td; a second reset transistor Tr2 having a gate electrode connected to a second reset control signal line of a plurality of second reset control signal lines rst2, a first electrode connected to a respective second reset signal line of a plurality of second reset signal lines Vint2, and a second electrode connected to the second electrode of the driving transistor, the second capacitor electrode Ce2 of the storage capacitor Cst, and an anode of a respective light emitting element LE; and a light emitting control transistor Te having a gate electrode connected to a respective light emitting control signal line of a plurality of light emitting control signal lines em, a first electrode connected to a respective voltage supply line of a plurality of voltage supply lines Vdd, and a second electrode connected to the first electrode of the driving transistor Td.

The pixel driving circuit further include a first node N1, a second node N2, and a third node N3. The first node N1 is connected to the gate electrode of the driving transistor Td, the first capacitor electrode Ce1, the second electrode of the data write transistor Tw, and the second electrode of the first reset transistor Tr1. The second node N2 is connected to the second electrode of the driving transistor Td, the second electrode of the second reset transistor Tr2, the second capacitor electrode Ce2 of the storage capacitor Cst, and the anode of the respective light emitting element LE. The third node N3 is connected to the second electrode of the light emitting control transistor Te and the first electrode of the driving transistor Td.

As used herein, a first electrode or a second electrode refers to one of a first terminal and a second terminal of a transistor, the first terminal and the second terminal being connected to an active layer of the transistor. A direction of a current flowing through the transistor may be configured to be from a first electrode to a second electrode, or from a second electrode to a first electrode. Accordingly, depending on the direction of the current flowing through the transistor, in one example, the first electrode is configured to receive an input signal and the second electrode is configured to output an output signal; in another example, the second electrode is configured to receive an input signal and the first electrode is configured to output. an output signal.

FIG. 2B is a timing diagram illustrating the operation of a pixel driving circuit in some embodiments according to the present disclosure. Referring to FIG. 2A and FIG. 2B, during one frame of image, the operation of the pixel driving circuit includes a reset sub-phase t1, a compensating sub-phase t2, a data write sub-phase t3, and a light emitting sub-phase t4.

In the reset sub-phase t1, a turning-on reset control signal is provided through the respective first reset control signal line of the plurality of first reset control signal lines rst1 to the gate electrode of the first reset transistor Tr1 to turn on the first reset transistor Tr1; allowing an initialization voltage signal from the respective first reset signal line of the plurality of first reset signal lines Vint1 to pass from a first electrode of the first reset transistor Tr1 to a second electrode of the first reset transistor Tr1, and in turn to the first capacitor electrode Ce1, the gate electrode of the driving transistor Td, and the node N1. The gate electrode of the driving transistor Td is initialized. A turning-on reset control signal is provided through the respective second reset control signal line of the plurality of second reset control signal line rst2 to the gate electrode of the second reset transistor Tr2 to turn on the second reset transistor Tr2; allowing an initialization voltage signal from the respective second reset signal line of the plurality of second reset signal lines Vint2 to pass from a first electrode of the second reset transistor Tr2 to a second electrode of the second reset transistor Tr2; and in turn to the node N2, The anode of the light emitting element LE is initialized.

In the compensating sub-phase t2, a turning-on light emitting control signal is provided through the respective light emitting control signal line of the plurality of light emitting control signal lines em to the gate electrode of the light emitting control transistor Te to tum on the light emitting control transistor Te. The second electrode of the driving transistor Td (e.g., the N2 node denoted in FIG. 2A) is charged until the voltage level at the second electrode of the driving transistor Td reaches a level of a reset signal provided by the respective first reset signal line of the plurality of first reset signal lines Vint1 minus a voltage level of a threshold voltage Vth of the driving transistor Td.

In the data write sub-phase t3, a turning-on gate scanning signal is provided through the respective gate line of the plurality of gate lines GL to the gate electrode of the data write transistor Tw to turn on the data write transistor Tw; allowing a data signal to pass from the first electrode of the data write transistor Tw to the second electrode of the data write transistor Tw, and in turn to the node N1. a voltage level at the gate electrode of the driving transistor Td reaches a voltage level of the data signal written to the gate electrode of the driving transistor Td. A capacitance of the storage capacitor Cst is far less than a capacitance of parasitic capacitance between a cathode of the light emitting element and the second capacitor electrode Ce2. The change in the voltage level at the gate electrode of the driving transistor Td does not affect the voltage level at the second electrode of the driving transistor Td (e.g., the N2 node). The voltage level at the second electrode of the driving transistor Td remains at the level of the reset signal provided by the respective first reset signal line of the plurality of first reset signal lines Vint1 minus the voltage level of the threshold voltage Vth of the driving transistor Td.

In the light emitting sub-phase t4, a turning-on light emitting control signal is provided through the respective light emitting control signal line of the plurality of light emitting control signal lines em to the gate electrode of the light emitting control transistor Te to turn on the light emitting control transistor Te. In the light emitting sub-phase t4, the driving transistor Td remains turned on. The light emitting element emits light. The voltage level at the N2 node changes to (Voled+Vss), wherein Voled stands for a voltage level for driving the light emitting element to emit light, Vss stands for a voltage level at the cathode of the light emitting element. Thus, the change in the voltage level at the N2 node is (Voled+Vss−(Vint 1−Vth)), wherein Vint1 stands for the level of the reset signal provided by the respective first reset signal line of the plurality of first reset signal lines Vint1, and Vth stands for the voltage level of the threshold voltage Vth of the driving transistor Td. Due to the bootstrapping effect of the storage capacitor Cst, the voltage level at the N1 node (the gate electrode of the driving transistor Td) becomes (Vdata+Vn2), wherein Vdata stands for the voltage level of the data signal, Vn2 stands for the change in the voltage level at the N2 node. The voltage level at the N1 node is Vdata+Voled+Vss−Vint1+Vth. A voltage difference Vgs between the gate electrode and the second electrode of the driving transistor Td is (Vdata−Vint1+Vth). A driving current I flowing through the driving transistor is correlated to (Vdata−Vint1)².

The present disclosure may be implemented in pixel driving circuit having transistors of various types, including a pixel driving circuit having p-type transistors, a pixel driving circuit having n-type transistors, and a pixel driving circuit having one or more p-type transistors and one or more n-type transistors. For a p-type transistor, an effective control signal (e.g., a turn-on control signal) is a low voltage signal, and an ineffective control signal (e.g., a turn-off control signal) is a high voltage signal. For an n-type transistor, an effective control signal (e.g., a turn-on control signal) is a high voltage signal, and an ineffective control signal (e.g., a turn-off control signal) is a low voltage signal. Referring to FIG. 2A, in some embodiments, all transistors in the pixel driving circuit are n-type transistors such as a metal oxide transistor.

The array substrate in some embodiments includes a plurality of subpixels. In some embodiments, the plurality of subpixels includes a respective first subpixel, a respective second subpixel, and a respective third subpixel. Optionally, a respective pixel of the array substrate includes the respective first subpixel, the respective second subpixel, and the respective third subpixel. The plurality of subpixels in the army substrate are arranged in an array. In one example, the array of the plurality of subpixels includes a S1-S2-S3 format repeating array, in which S1 stands for the respective first subpixel, S2 stands for the respective second subpixel, and S3 stands for the respective third subpixel. In another example, the S1-S2-S3 format is a C1-C2-C3 format, in which C1 stands for the respective first subpixel of a first color, C2 stands for the respective second subpixel of a second color, and C3 stands for the respective third subpixel of a third color. In another example, the C1-C2-C3 format is an R-G-B format, in which the respective first subpixel is a red subpixel, the respective second subpixel is a green subpixel, and the respective third subpixel is a blue subpixel.

In another example, the array of the plurality of subpixels includes a S1-S2-S3-S4 format repeating array, in which S1 stands for the respective first subpixel, S2 stands for the respective second subpixel, S3 stands for the respective third subpixel, and S4 stands for the respective fourth subpixel. In another example, the S1-S2-S3-S4 format is a C1-C2-C3-C4 format, in which C1 stands for the respective first subpixel of a first color, C2 stands for the respective second subpixel of a second color, C3 stands for the respective third subpixel of a third color, and C4 stands for the respective fourth subpixel of a fourth color. In another example, the S1-S2-S3-S4 format is a C1-C2-C3-C2′ format, in which C1 stands for the respective first subpixel of a first color, C2 stands for the respective second subpixel of a second color, C3 stands for the respective third subpixel of a third color, and C2′ stands for the respective fourth subpixel of the second color. In another example, the C1-C2-C3-C2′ format is a R-G-B-G format, in which the respective first subpixel is a red subpixel, the respective second subpixel is a green subpixel, the respective third subpixel is a blue subpixel, and the respective fourth subpixel is a green subpixel.

In some embodiments, a minimum repeating unit of the plurality of subpixels of the array substrate includes a respective first subpixel, a respective second subpixel, and a respective third subpixel. Optionally, each of the respective first subpixel, the respective second subpixel, and the respective third subpixel, includes the data write transistor Tw, the first reset transistor Tr1, the second reset transistor Tr2, the light emitting control transistor Te, the driving transistor Td, and the storage capacitor Cst.

In alternative embodiments, a minimum repeating unit of the plurality of subpixels of the array substrate includes a respective first subpixel, a respective second subpixel, a respective third subpixel, and a respective fourth subpixel. Optionally, each of the respective first subpixel, the respective second subpixel, the respective third subpixel, and the respective fourth subpixel, includes the data write transistor Tw, the first reset transistor Tr1, the second reset transistor Tr2, the light emitting control transistor Te, the driving transistor Td, and the storage capacitor Cst.

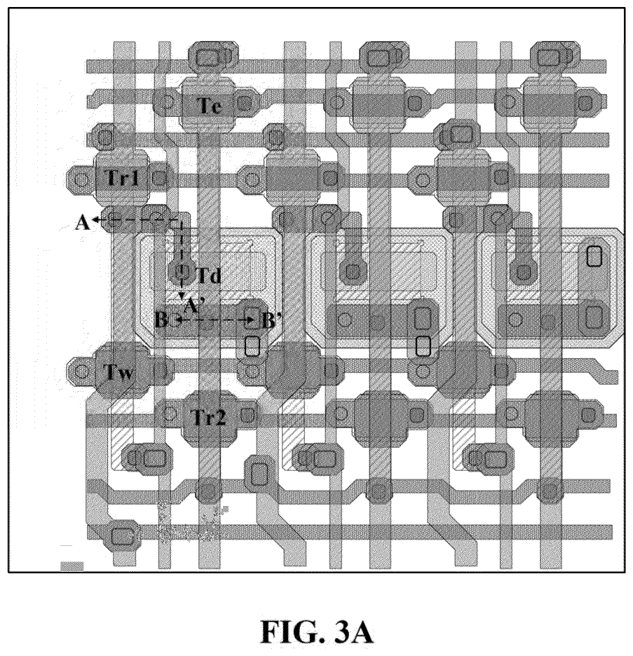

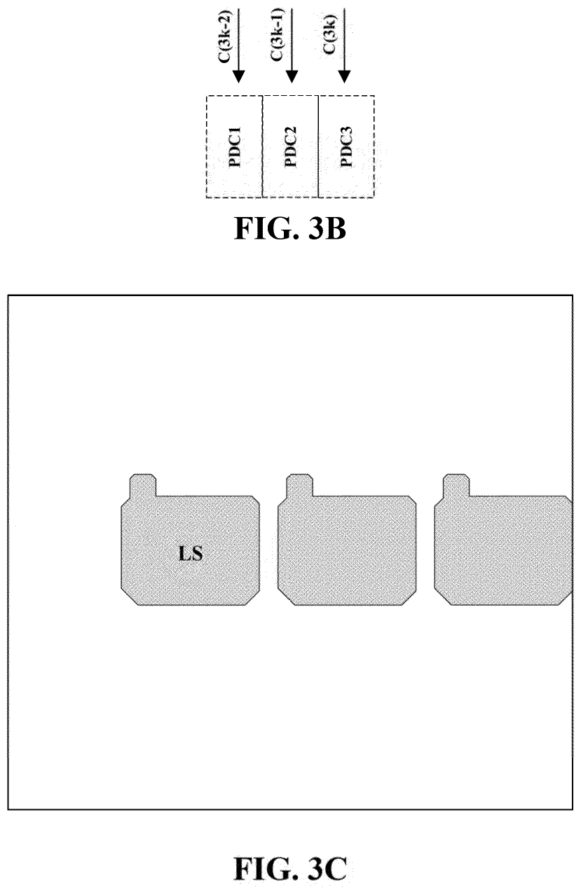

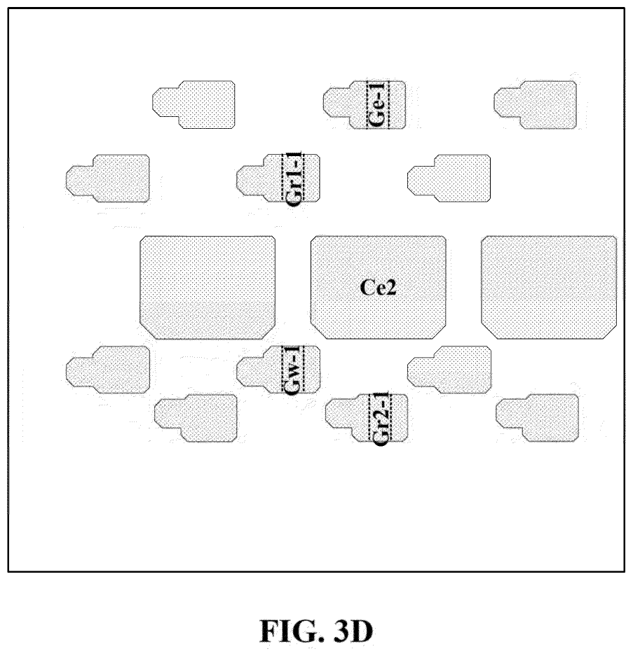

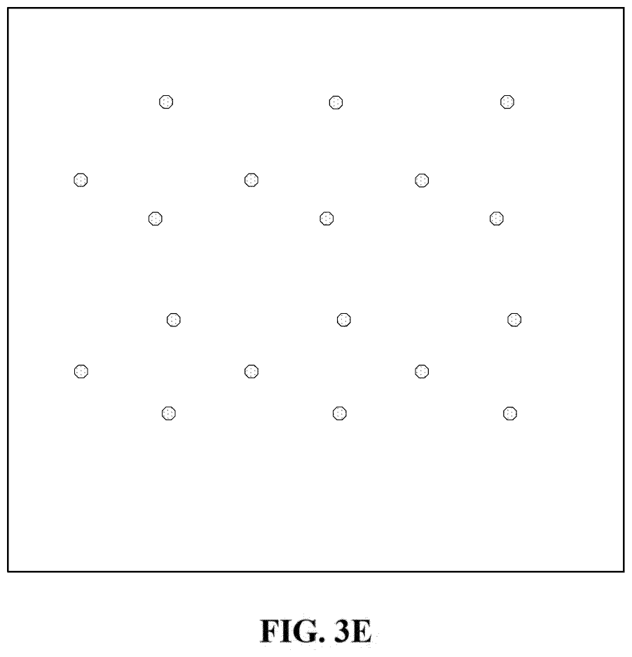

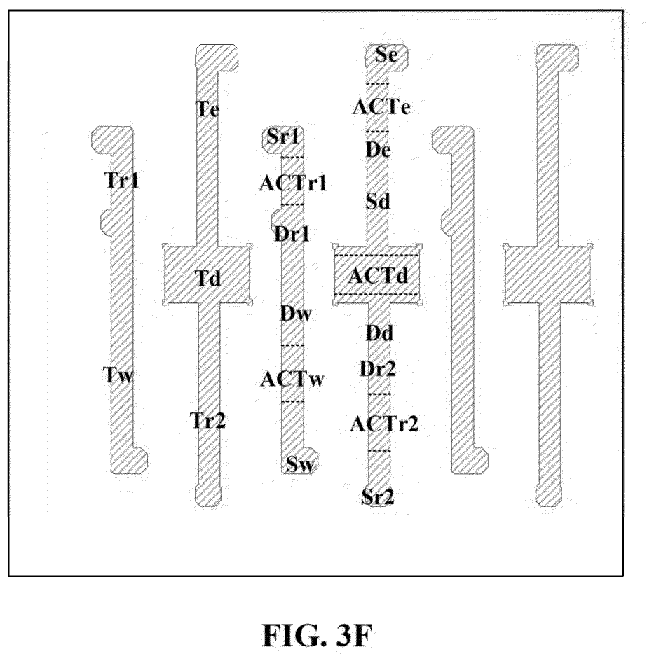

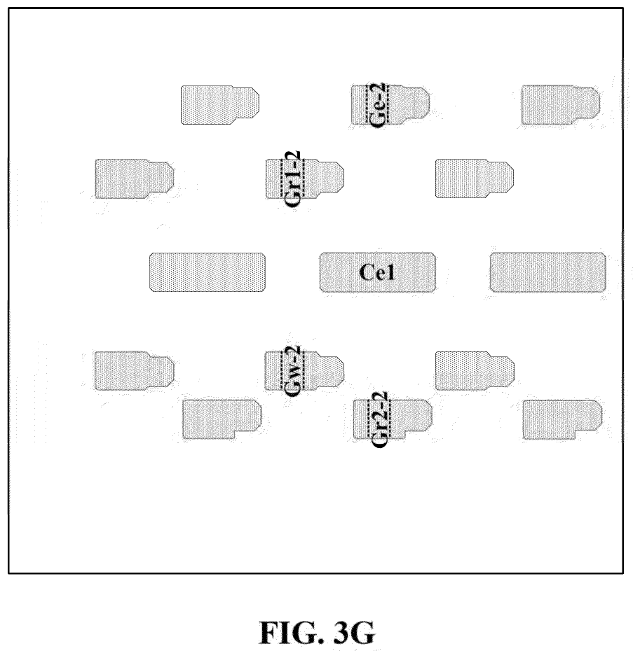

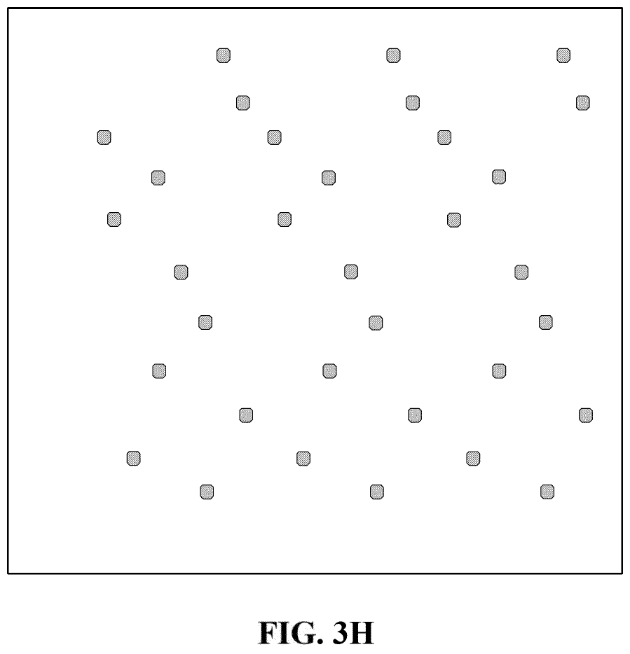

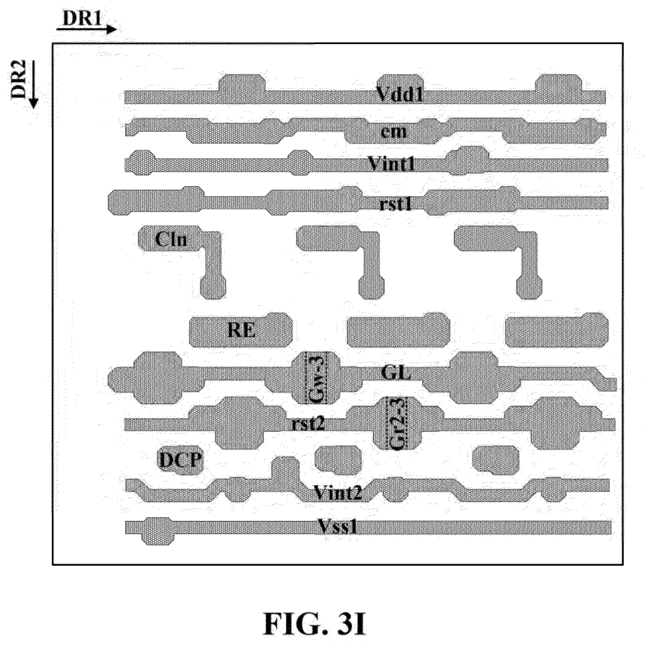

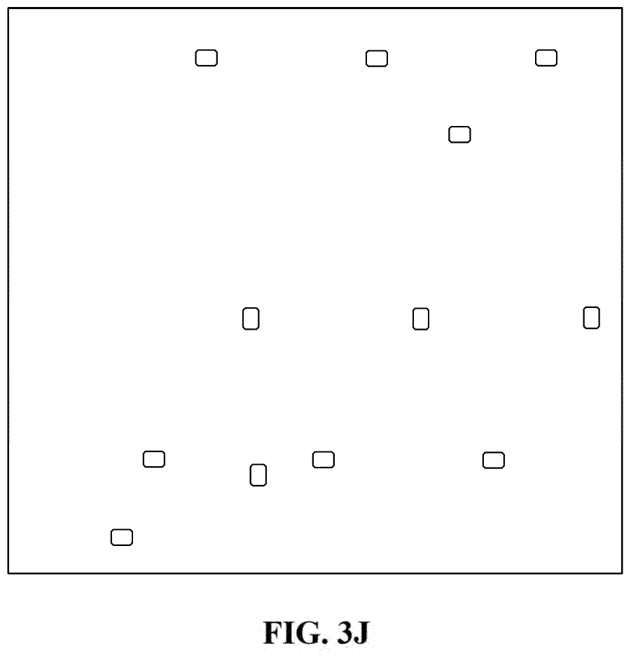

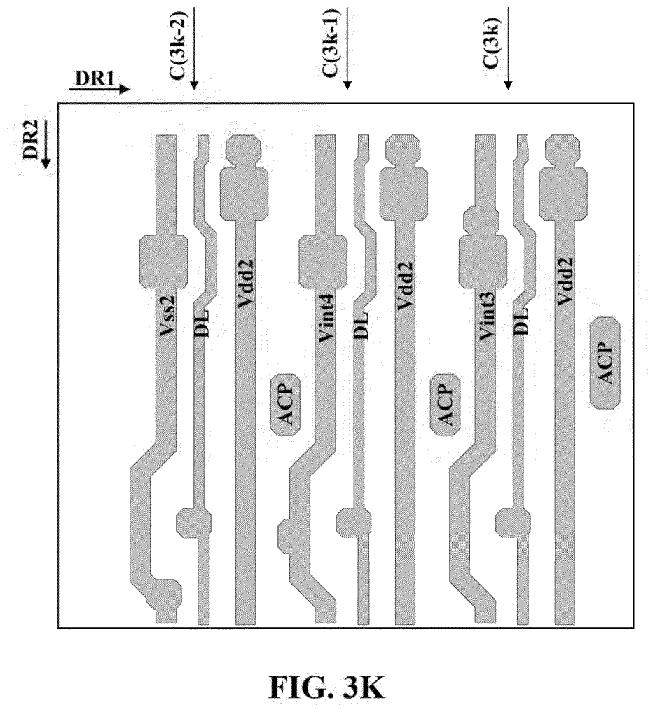

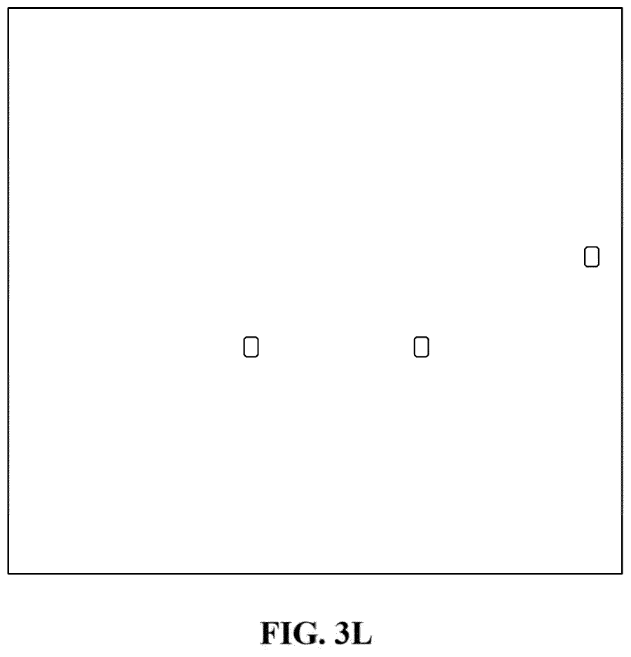

FIG. 3A is a diagram illustrating the structure of a portion of an array substrate in some embodiments according to the present disclosure. FIG. 3B is a schematic diagram illustrating an arrangement of a plurality of pixel driving circuits in a portion of an array substrate depicted in FIG. 3A. FIG. 3A and FIG. 3B depicts a portion of the array substrate having three pixel driving circuits, including PDC1, PDC2, and PDC3.

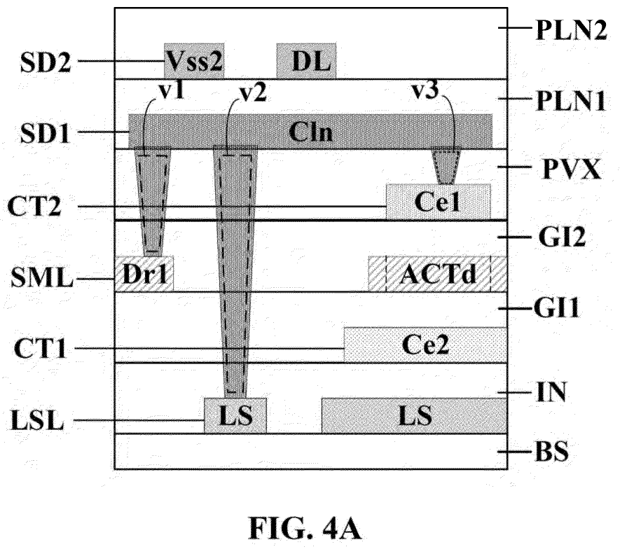

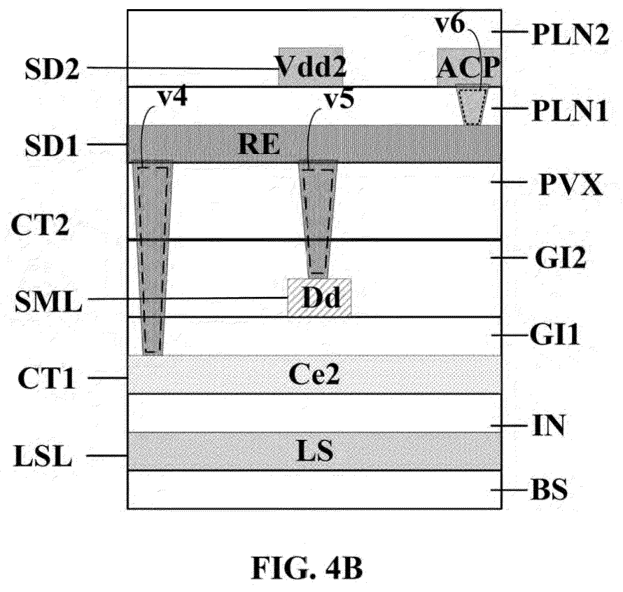

FIG. 3C is a diagram illustrating the structure of a light shield layer in the portion of the array substrate depicted in FIG. 3A. FIG. 3D is a diagram illustrating the structure of a first conductive layer in the portion of the array substrate depicted in FIO. 3A. FIG. 3E is a diagram illustrating the structure of a first gate insulating layer in the portion of the array substrate depicted in FIG. 3A. FIG. 3F is a diagram illustrating the structure of a semiconductor material layer in the portion of the array substrate depicted in FIG. 3A. FIG. 3G is a diagram illustrating the structure of a second conductive layer in the portion of the array substrate depicted in FIG. 3A. FIG. 3H is a diagram illustrating the structure of a passivation layer in the portion of the array substrate depicted in FIG. 3A. FIG. 3I is a diagram illustrating the structure of a first signal line layer in the portion of the array substrate depicted in FIG. 3A. FIG. 3J is a diagram illustrating the structure of a first planarization layer in the portion of the array substrate depicted in FIG. 3A. FIG. 3K is a diagram illustrating the structure of a second signal line layer in the portion of the array substrate depicted in FIG. 3A. FIG. 3L is a diagram illustrating the structure of a second planarization layer in the portion of the array substrate depicted in FIG. 3A. FIG. 4A is a cross-sectional view along an A-A′ line in FIG. 3A. FIG. 4B is a cross-sectional view along a B-B′ line in FIG. 3A.

Referring to FIG. 3A to FIG. 3L, and FIG. 4A to FIG. 4B, in some embodiments, the array substrate includes a base substrate BS, a light shield layer LSL on the base substrate BS, an insulating layer IN on a side of the light shield layer LSL away from the base substrate BS, a first conductive layer CT1 on a side of the insulating layer IN away from the light shield layer LSL, a first gate insulating layer GI1 on a side of the first conductive layer CT1 away from the insulating layer IN, a semiconductor material layer SML on a side of the first gate insulating layer GI1 away from the first conductive layer CT1, a second gate insulating layer GI2 on a side of the semiconductor material layer SML away from the first gate insulating layer GI1, a second conductive layer CT2 on a side of the second gate insulating layer GI2 away from the semiconductor material layer SML, a passivation layer PVX on a side of the second conductive layer CT2 away from the second gate insulating layer GI2, a first signal line layer SD1 on a side of the passivation layer PVX away from the second conductive layer CT2, a first planarization layer PLN1 on a side of the first signal line layer SD1 away from the passivation layer PVX, a second signal line layer SD2 on a side of the first planarization layer PLN1 away from the first signal line layer SD1, and a second planarization layer PLN2 on a side of the second signal line layer SD2 away from the first planarization layer PLN1.

Referring to FIG. 2A, FIG. 3A, and FIG. 3C, in some embodiments, the light shield layer LSL includes a light shield LS. Various appropriate materials and various appropriate fabricating methods may be used for making the light shield layer LSL. For example, a metallic material may be deposited on the substrate by a plasma-enhanced chemical vapor deposition (PECVD) process. Examples of appropriate metallic materials for making the light shield layer LSL include, but are not limited to, aluminum, chromium, tungsten, titanium, tantalum, molybdenum, copper, and alloys or laminates containing the same.

In some embodiments, the array substrate includes a plurality of light shields respectively in a plurality of pixel driving circuits. The plurality of light shields are spaced apart from each other.

In some embodiments, referring to FIG. 2A, FIG. 3A, FIG. 3C, and FIG. 4A, an orthographic projection of the light shield LS on a base substrate BS substantially covers (e.g., at least 80% covers, at least 85% covers, at least 90% covers, at least 95% covers, at least 99% covers, or completely covers) an orthographic projection of the active layer ACTd of the driving transistor Td on the base substrate BS. The inventors of the present disclosure discover that, by having this structure, the active layer ACTd of the driving transistor Td can be protected from irradiation and stabilized.

In some embodiments, the light shield LS is electrically connected to the gate electrode of the driving transistor Td (e.g., the first capacitor electrode Ce1 of the storage capacitor Cst which functions as the light shield LS). Optionally, the light shield LS is electrically connected to the gate electrode of the driving transistor Td through a node connecting line Cln in the first signal line layer SD1. The inventors of the present disclosure discover that, surprisingly and unexpected, by having the light shield LS electrically connected to the gate electrode of the driving transistor Td, the low grayscale driving capability of the driving transistor Td can be significantly improved, resulting in enhanced performance of the driving transistor Td.

In some embodiments, the light shield LS is electrically connected to the second electrode Dr1 of the first reset transistor Tr1. Optionally, the light shield LS is electrically connected to the second electrode Dr1 of the first reset transistor Tr1 through the node connecting line Cln in the first signal line layer SD1.

In some embodiments, an orthographic projection of the light shield LS on a base substrate BS substantially covers (e.g., at least 80% covers, at least 85% covers, at least 90% covers, at least 95% covers, at least 99% covers, or completely covers) an orthographic projection of the gate electrode of the driving transistor Td on the base substrate BS.

In some embodiments, an orthographic projection of the light shield LS on a base substrate BS substantially covers (e.g., at least 80% covers, at least 85% covers, at least 90% covers, at least 95% covers, at least 99% covers, or completely covers) an orthographic projection of the second capacitor electrode Ce2 of the storage capacitor Cst on the base substrate BS.

Referring to FIG. 2A, FIG. 3A, and FIG. 3D, the first conductive layer in some embodiments includes a second capacitor electrode Ce2 of the storage capacitor Cst, a first gate electrode portion Gw-1 of the gate electrode of the data write transistor Tw, a first gate electrode portion Gr1-1 of the gate electrode of the first reset transistor Tr1, a first gate electrode portion Gr2-1 of the gate electrode of the second reset transistor Tr2, and a first gate electrode portion Ge-1 of the gate electrode of the light emitting control transistor Te. Various appropriate electrode materials and various appropriate fabricating methods may be used to make the first conductive layer. For example, a conductive material may be deposited on the substrate by a plasma-enhanced chemical vapor deposition (PECVD) process and patterned. Examples of appropriate conductive materials for making the first conductive layer include, but are not limited to, aluminum, copper, molybdenum, chromium, aluminum copper alloy, copper molybdenum alloy, molybdenum aluminum alloy, aluminum chromium alloy, copper chromium alloy, molybdenum chromium alloy, copper molybdenum aluminum alloy, and the like. Optionally, the second capacitor electrode Ce2 of the storage capacitor Cst, a first gate electrode portion Gw-1 of the gate electrode of the data write transistor Tw, the first gate electrode portion Gr1-1 of the gate electrode of the first reset transistor Tr1, the first gate electrode portion Gr2-1 of the gate electrode of the second reset transistor Tr2, and the first gate electrode portion Ge-1 of the gate electrode of the light emitting control transistor Te are in a same layer.

As used herein, the term “same layer” refers to the relationship between the layers simultaneously formed in the same step. In one example, the second capacitor electrode Ce2 and the first gate electrode portion Gw-1 are in a same layer when they are formed as a result of one or more steps of a same patterning process performed in a same layer of material. In another example, the second capacitor electrode Ce2 and the first gate electrode portion Gw-1 can be formed in a same layer by simultaneously performing the step of forming the second capacitor electrode Ce2, and the step of forming the first gate electrode portion Gw-1. The term “same layer” does not always mean that the thickness of the layer or the height of the layer in a cross-sectional view is the same.

Referring to FIG. 2A, FIG. 3A, FIG. 3D, and FIG. 3I, in some embodiments, the gate electrode of the data write transistor Tw includes one or more portions. In some embodiments, the first gate electrode portion Gw-1 of the gate electrode of the data write transistor Tw is connected to a respective gate line of the plurality of gate lines GL.

Referring to FIG. 2A, FIG. 3A, FIG. 3D, and FIG. 3I, in some embodiments, the gate electrode of the first reset transistor Tr1 includes one or more portions. In some embodiments, the first gate electrode portion Gr1-1 of the gate electrode of the first reset transistor Tr1 is connected to a respective first reset control signal line of the plurality of first reset control signal lines rst1.

Referring to FIG. 2A, FIG. 3A, FIG. 3D, and FIG. 3I, in some embodiments, the gate electrode of the second reset transistor Tr2 includes one or more portions. In some embodiments, the first gate electrode portion Gr2-1 of the gate electrode of the second reset transistor Tr2 is connected to a respective second reset control signal line of the plurality of second reset control signal lines rst2.

Referring to FIG. 2A, FIG. 3A, FIG. 3D, and FIG. 3I, in some embodiments, the gate electrode of the light emitting control transistor Te includes one or more portions. In some embodiments, the first gate electrode portion Ge-1 of the gate electrode of the light emitting control transistor Te is connected to a respective light emitting control signal line of the plurality of light emitting control signal lines em.

Vias extending through the first gate insulating layer GI1 are depicted in FIG. 3E.

Referring to FIG. 2A, FIG. 3A, and FIG. 3F, the semiconductor material layer SML in some embodiments includes at least an active layer ACTd of the driving transistor Td, an active layer ACTr1 of the first reset transistor Tr1, an active layer ACTr2 of the second reset transistor Tr2, an active layer ACTw of the data write transistor Tw, and an active layer ACTe of the light emitting control transistor Te. Optionally, the semiconductor material layer SML further includes at least a portion of a first electrode Sd of the driving transistor Td, at least a portion of a first electrode Sr1 of the first reset transistor Tr1, at least a portion of a first electrode Sr2 of the second reset transistor Tr2, at least a portion of a first electrode Sw of the data write transistor Tw, and at least a portion of a first electrode Se of the light emitting control transistor Te. Optionally, the semiconductor material layer SML further includes at least a portion of a second electrode Dd of the driving transistor Td, at least a portion of a second electrode Dr1 of the first reset transistor Tr1, at least a portion of a second electrode Dr2 of the second reset transistor Tr2, at least a portion of a second electrode Dw of the data write transistor Tw, and at least a portion of a second electrode De of the light emitting control transistor Te. Optionally, the semiconductor material layer SML includes the active layer ACTd, the first electrode Sd, and the second electrode Dd of the driving transistor Td; the active layer ACTr1, the first electrode Sr1, and the second electrode Dr1 of the first reset transistor Tr1; the active layer ACTr2, the first electrode Sr2, and the second electrode Dr2 of the second reset transistor Tr2; the active layer ACTw, the first electrode Sw, and the second electrode Dw of the data write transistor Tw; and the active layer ACTe, the first electrode Se, and the second electrode De of the light emitting control transistor Te. Various appropriate semiconductor materials may be used for making the semiconductor material layer SML. Examples of the semiconductor materials for making the semiconductor material layer SML include metal oxide-based semiconductor material such as indium gallium zinc oxide and metal oxynitride-based semiconductor materials such as zinc oxynitride.

As used herein, the active layer refers to a component of the transistor comprising at least a portion of the semiconductor material layer whose orthographic projection on the base substrate overlaps with an orthographic projection of a gate electrode on the base substrate. A first electrode refers to a component of the transistor connected to one side of the active layer, and a second electrode refers to a component of the transistor connected to another side of the active layer. In the context of a double-gate type transistor, the active layer refers to a component of the transistor comprising a first portion of the semiconductor material layer whose orthographic projection on the base substrate overlaps with an orthographic projection of a first gate on the base substrate, a second portion of the semiconductor material layer whose orthographic projection on the base substrate overlaps with an orthographic projection of a second gate on the base substrate, and a third portion between the first portion and the second portion. In the context of a double-gate type transistor, a first electrode refers to a component of the transistor connected to a side of the first portion distal to the third portion, and a second electrode refers to a component of the transistor connected to a side of the second portion distal to the third portion.

FIG. 3F is annotated with labels indicating components of transistors in the pixel driving circuit. For example, the driving transistor Td includes an active layer ACTd, a first electrode Sd, and a second electrode Dd; the data write transistor Tw includes an active layer ACTw, a first electrode Sw, and a second electrode Dw; the light emitting control transistor Tw includes an active layer ACTe, a first electrode Se, and a second electrode De; the first reset transistor Tr1 includes an active layer ACTr1, a first electrode Sr1, and a second electrode Dr1; and the second reset transistor Tr2 includes an active layer ACTr2, a first electrode Sr2, and a second electrode Dr2. Optionally, the active layer ACTd of the driving transistor Td, the active layer ACTe of the light emitting control transistor Te, and the active layer ACTr2 of the second reset transistor Tr2 are parts of a first unitary structure. Optionally, the active layer ACTd, the first electrode Sd, and the second electrode Dd of the driving transistor Td; the active layer ACTe, the first electrode Se, and the second electrode De of the light emitting control transistor Te; and the active layer ACTr2, the first electrode Sr2, and the second electrode Dr2 of the second reset transistor Tr2 are parts of the first unitary structure. Optionally, the active layer ACTw of the data write transistor Tw and the active layer ACTr1 of the first reset transistor Tr1 are parts of a second unitary structure. Optionally, the active layer ACTw, the first electrode Sw, and the second electrode Dw of the data write transistor Tw and the active layer ACTr1, the first electrode Sr1, and the second electrode Dr1 of the first reset transistor Tr1 are parts of the second unitary structure.

Referring to FIG. 2A, FIG. 3A, and FIG. 3G, the second conductive layer in some embodiments includes a first capacitor electrode Ce1 of the storage capacitor Cst, a second gate electrode portion Gw-2 of the gate electrode of the data write transistor Tw, a second gate electrode portion Gr1-2 of the gate electrode of the first reset transistor Tr1, a second gate electrode portion Gr2-2 of the gate electrode of the second reset transistor Tr2, and a second gate electrode portion Ge-2 of the gate electrode of the light emitting control transistor Te. Various appropriate electrode materials and various appropriate fabricating methods may be used to make the second conductive layer. For example, a conductive material may be deposited on the substrate by a plasma-enhanced chemical vapor deposition (PECVD) process and patterned. Examples of appropriate conductive materials for making the second conductive layer include, but are not limited to, aluminum, copper, molybdenum, chromium, aluminum copper alloy, copper molybdenum alloy, molybdenum aluminum alloy, aluminum chromium alloy, copper chromium alloy, molybdenum chromium alloy, copper molybdenum aluminum alloy, and the like. Optionally, the first capacitor electrode Ce1 of the storage capacitor Cst, the second gate electrode portion Gw-2 of the gate electrode of the data write transistor Tw, the second gate electrode portion Gr1-2 of the gate electrode of the first reset transistor Tr1, the second gate electrode portion Gr2-2 of the gate electrode of the second reset transistor Tr2, and the second gate electrode portion Ge-2 of the gate electrode of the light emitting control transistor Te are in a same layer.

Referring to FIG. 2A, FIG. 3A, FIG. 3G, and FIG. 3I, in some embodiments, the gate electrode of the data write transistor Tw includes one or more portions. In some embodiments, the second gate electrode portion Gw-2 of the gate electrode of the data write transistor Tw is connected to a respective gate line of the plurality of gate lines GL.

Referring to FIG. 2A, FIG. 3A, FIG. 3G, and FIG. 3I, in some embodiments, the gate electrode of the first reset transistor Tr1 includes one or more portions. In some embodiments, the second gate electrode portion Gr1-2 of the gate electrode of the first reset transistor Tr1 is connected to a respective first reset control signal line of the plurality of first reset control signal lines rst1.

Referring to FIG. 2A, FIG. 3A, FIG. 3G, and FIG. 3I, in some embodiments, the gate electrode of the second reset transistor Tr2 includes one or more portions. In some embodiments, the second gate electrode portion Gr2-2 of the gate electrode of the second reset transistor Tr2 is connected to a respective second reset control signal line of the plurality of second reset control signal lines rst2.

Referring to FIG. 2A, FIG. 3A, FIG. 3G, and FIG. 3I, in some embodiments, the gate electrode of the light emitting control transistor Te includes one or more portions. In some embodiments, the second gate electrode portion Ge-2 of the gate electrode of the light emitting control transistor Te is connected to a respective light emitting control signal line of the plurality of light emitting control signal lines em.

Vias extending through the passivation layer PVX are depicted in FIG. 3H.

Referring to FIG. 2A, FIG. 3A, and FIG. 3I, the first signal line layer in some embodiments includes a node connecting line Cln, a plurality of first voltage supply lines Vdd1, a plurality of second voltage supply lines Vss1, a plurality of first reset signal lines Vint1, a plurality of second reset signal lines Vint2, a plurality of first reset control signal lines rst1, a plurality of second reset control signal lines rst2, a plurality of gate lines GL, a plurality of light emitting control signal lines em, a relay electrode RE, and a data signal connecting pad DCP.

Various appropriate conductive materials and various appropriate fabricating methods may be used to make the first signal line layer. For example, a conductive material may be deposited on the substrate by a plasma-enhanced chemical vapor deposition (PECVD) process and patterned. Examples of appropriate conductive materials for making the first signal line layer include, but are not limited to, titanium, aluminum, copper, molybdenum, chromium, aluminum copper alloy, copper molybdenum alloy, molybdenum aluminum alloy, aluminum chromium alloy, copper chromium alloy, molybdenum chromium alloy, copper molybdenum aluminum alloy, and the like. In some embodiments, the first signal line layer includes a plurality of sub-layers stacked together. In one example, the first signal line layer includes a stacked titanium/aluminum/titanium multi-layer structure. In another example, the first signal line layer includes a stacked molybdenum/aluminum/molybdenum multi-layer structure. Optionally, the node connecting line Cln, the plurality of first voltage supply lines Vdd1, the plurality of second voltage supply lines Vss1, the plurality of first reset signal lines Vint1, the plurality of second reset signal lines Vint2, the plurality of first reset control signal lines rst1, the plurality of second reset control signal lines rst2, the plurality of gate lines GL, and the plurality of light emitting control signal lines em, the relay electrode RE, and the anode connecting pad ACP are in a same layer.

In some embodiments, the plurality of first voltage supply lines Vdd1, the plurality of second voltage supply lines Vss1, the plurality of first reset signal lines Vint1, the plurality of second reset signal lines Vint2, the plurality of first reset control signal lines rst1, the plurality of second reset control signal lines rst2, the plurality of gate lines GL, and the plurality of light emitting control signal lines em extend along a direction substantially parallel to the first direction DR1, respectively. As used herein, the term “substantially parallel” means that an angle is in the range of 0 degree to approximately 45 degrees, e.g., 0 degree to approximately 5 degrees, 0 degree to approximately 10 degrees, 0 degree to approximately 15 degrees, 0 degree to approximately 20 degrees, 0 degree to approximately 25 degrees, 0 degree to approximately 30 degrees.

In some embodiments, the plurality of first voltage supply lines Vdd1 are configured to provide a first reference voltage signal (e.g., a high reference voltage signal); and the plurality of second voltage supply lines Vss1 are configured to provide a second reference voltage signal (e.g., a low reference voltage signal). Optionally, the first reference voltage signal is a constant voltage signal, the second reference voltage signal is a constant voltage signal, the first reference voltage signal has a voltage level higher than a voltage level of the second reference voltage signal.

The node connecting line Cln connects the gate electrode of the driving transistor Td in a respective pixel driving circuit with the second electrode of the first reset transistor Tr1 and the light shield in the respective pixel driving circuit together. Referring to FIG. 4A, in some embodiments, the node connecting line Cln is connected to the second electrode Dr1 of the first reset transistor Tr1 through a first via v1, to the light shield LS through a second via v2, and to the gate electrode of the driving transistor Td through a third via v3. Optionally, the first node connecting line Cln1 corresponds to the node N1 depicted in FIG. 2A.

In one example, the first via v1 extends through the passivation layer PVX and the second gate insulating layer GI2; the second via v2 extends through the passivation layer PVX, the second gate insulating layer GI2, the first gate insulating layer GI1, and the insulating layer IN; and the third via v3 extends through the passivation layer PVX.

The data signal connecting pad DCP connects a respective data line of the plurality of data lines DL to a first electrode of the data write transistor Tw.

The relay electrode RE connects an anode connecting pad with the second capacitor electrode Ce2 and/or the second electrode Dd of the driving transistor Td in a respective pixel driving circuit. The anode connecting pad is connected to an anode of a respective light emitting element. Referring to FIG. 4B, in some embodiments, the relay electrode RE is connected to the second capacitor electrode Ce2 through a fourth via v4, to the second electrode Dd of the driving transistor Td through a fifth via v5. The anode connecting pad ACP is connected to the relay electrode RE through a sixth via v6. Optionally, the relay electrode RE corresponds to the node N2 depicted in FIG. 2A.

In one example, the fourth vin v4 extends through the passivation layer PVX, the second gate insulating layer GI2, and the first gate insulating layer GI1; the fifth via v5 extends through the passivation layer PVX and the second gate insulating layer GI2; and the sixth via v6 extends through the first planarization layer PLN1.

In some embodiments, a respective first voltage supply line of the plurality of first voltage supply lines Vdd1 is connected to first electrodes of multiple light emitting control transistors, e.g., multiple light emitting control transistors in a same row.

In some embodiments, the plurality of second voltage supply lines Vss1 are electrically connected to a cathode of a plurality of light emitting elements.

In some embodiments, a respective first reset signal line of the plurality of first reset signal lines Vint1 is connected to first electrodes of multiple first reset transistors, e.g., multiple first reset transistors in a same row.

In some embodiments, a respective second reset signal line of the plurality of second reset signal lines Vint2 is connected to first electrodes of multiple second reset transistors, e.g., multiple second reset transistors in a same row.

In some embodiments, a respective gate line of the plurality of gate lines GL includes a third gate electrode portion Gw-3 of the gate electrode of the data write transistor Tw. Optionally, an orthographic projection of the third gate electrode portion Gw-3 of the gate electrode of the data write transistor Tw on a base substrate at least partially overlaps with an orthographic projection of the second gate electrode portion Gw-2 of the gate electrode of the data write transistor Tw on the base substrate; and at least partially overlaps with an orthographic projection of the first gate electrode portion Gw-1 of the gate electrode of the data write transistor Tw on the base substrate. Optionally, the orthographic projection of the second gate electrode portion Gw-2 of the gate electrode of the data write transistor Tw on the base substrate at least partially overlaps with the orthographic projection of the first gate electrode portion Gw-1 of the gate electrode of the data write transistor Tw on the base substrate.

In some embodiments, a respective second reset control signal line of the plurality of second reset control signal lines rst2 includes a third gate electrode portion Gr2-3 of the gate electrode of the second reset transistor Tr2. Optionally, an orthographic projection of the third gate electrode portion Gr2-3 of the gate electrode of the second reset transistor Tr2 on a base substrate at least partially overlaps with an orthographic projection of the second gate electrode portion Gr2-2 of the gate electrode of the second reset transistor Tr2 on the base substrate; and at least partially overlaps with an orthographic projection of the first gate electrode portion Gr2-1 of the gate electrode of the second reset transistor Tr2 on the base substrate. Optionally, the orthographic projection of the second gate electrode portion Gr2-2 of the gate electrode of the second reset transistor Tr2 on the base substrate at least partially overlaps with the orthographic projection of the first gate electrode portion Gr2-1 of the gate electrode of the second reset transistor Tr2 on the base substrate.

Vias extending through the first planarization layer PLN1 are depicted in FIG. 3J.

Referring to FIG. 2A, FIG. 3A, and FIG. 3K, the second signal line layer in some embodiments includes a plurality of third voltage supply lines Vdd2, a plurality of fourth voltage supply lines Vss2, a plurality of data line DL, a plurality of third reset signal lines Vint3, a plurality of fourth reset signal lines Vint4, and an anode connecting pad ACP. A respective data line of the plurality of data lines DL is electrically connected to a first electrode of the data write transistor Tw through a data signal connecting pad. The anode connecting pad ACP is connected to the second capacitor electrode and/or the second electrode of the driving transistor in a respective pixel driving circuit through the relay electrode, and is connected to an anode of a respective light emitting element.

Various appropriate conductive materials and various appropriate fabricating methods may be used to make the second signal line layer. For example, a conductive material may be deposited on the substrate by a plasma-enhanced chemical vapor deposition (PECVD) process and patterned. Examples of appropriate conductive materials for making the second signal line layer include, but are not limited to, titanium, aluminum, copper, molybdenum, chromium, aluminum copper alloy, copper molybdenum alloy, molybdenum aluminum alloy, aluminum chromium alloy, copper chromium alloy, molybdenum chromium alloy, copper molybdenum aluminum alloy, and the like. In some embodiments, the second signal line layer includes a plurality of sub-layers stacked together. In one example, the second signal line layer includes a stacked titanium/aluminum/titanium multi-layer structure. In another example, the second signal line layer includes a stacked molybdenum/aluminum/molybdenum multi-layer structure. Optionally, the plurality of third voltage supply lines Vdd2, the plurality of fourth voltage supply lines Vss2, the plurality of data line DL, the plurality of third reset signal lines Vint3, the plurality of fourth reset signal lines Vint4, and the anode connecting pad ACP are in a same layer.

In some embodiments, the plurality of third voltage supply lines Vdd2 are configured to provide a first reference voltage signal (e.g., a high reference voltage signal); and the plurality of fourth voltage supply lines Vss2 are configured to provide a second reference voltage signal (e.g., a low reference voltage signal). Optionally, the first reference voltage signal is a constant voltage signal, the second reference voltage signal is a constant voltage signal, the first reference voltage signal has a voltage level higher than a voltage level of the second reference voltage signal.

Referring to FIG. 3I and FIG. 3K, in some embodiments, the plurality of third voltage supply lines Vdd2 in the second signal line layer are connected to a plurality of first voltage supply lines Vdd1 in the first signal line layer. A respective first voltage supply line of the plurality of first voltage supply lines Vdd1 is connected to first electrodes of multiple light emitting control transistors, e.g., multiple light emitting control transistors in a same row. Optionally, the plurality of third voltage supply lines Vdd2 extend along a direction substantially parallel to a second direction DR2; and the plurality of first voltage supply lines Vdd1 extend along a direction substantially parallel to the first direction DR1.

In some embodiments, the plurality of fourth voltage supply lines Vss2 in the second signal line layer are connected to a plurality of second voltage supply lines Vss1 in the first signal line layer. Optionally, the plurality of fourth voltage supply lines Vss2 extend along a direction substantially parallel to a second direction DR2; and the plurality of second voltage supply lines Vss1 extend along a direction substantially parallel to the first direction DR1.

In some embodiments, the plurality of third reset signal lines Vint3 in the second signal line layer are connected to a plurality first reset signal lines Vint1 in the first signal line layer. Optionally, a respective first reset signal line of the plurality of first reset signal lines Vint1 is connected to first electrodes of multiple first reset transistors, e.g., multiple first reset transistors in a same row. Optionally, the plurality of third reset signal lines Vint3 extend along a direction substantially parallel to a second direction DR2; and the plurality first reset signal lines Vint1 extend along a direction substantially parallel to the first direction DR1.

In some embodiments, the plurality of fourth reset signal lines Vint4 in the second signal line layer are connected to a plurality second reset signal lines Vint2 in the first signal line layer. Optionally, a respective second reset signal line of the plurality of second reset signal lines Vint2 is connected to first electrodes of multiple second reset transistors, e.g., multiple second reset transistors in a same row. Optionally, the plurality of fourth reset signal lines Vint4 extend along a direction substantially parallel to a second direction DR2; and the plurality second reset signal lines Vint2 extend along a direction substantially parallel to the first direction DR1.

In some embodiments, the first column of pixel driving circuits, the second column of pixel driving circuits, and the third column of pixel driving circuits are three adjacent columns of pixel driving circuits. Optionally, the first column of pixel driving circuits, the second column of pixel driving circuits, and the third column of pixel driving circuits are sequentially arranged along the first direction DR1.

In some embodiments, a respective data line of the plurality of data lines DL in the second signal line layer is connected to a data signal connecting pad DCP in the first signal line layer, and the data signal connecting pad DCP is connected to a first electrode of the data write transistor Tw. Optionally, the plurality of data lines DL extend along a direction substantially parallel to a second direction DR2.

Vias extending through the second planarization layer PLN2 are depicted in FIG. 3L. An anode of a light emitting element is connected to an anode connecting pad in the second signal line layer through a via extending through the second planarization layer PLN2.

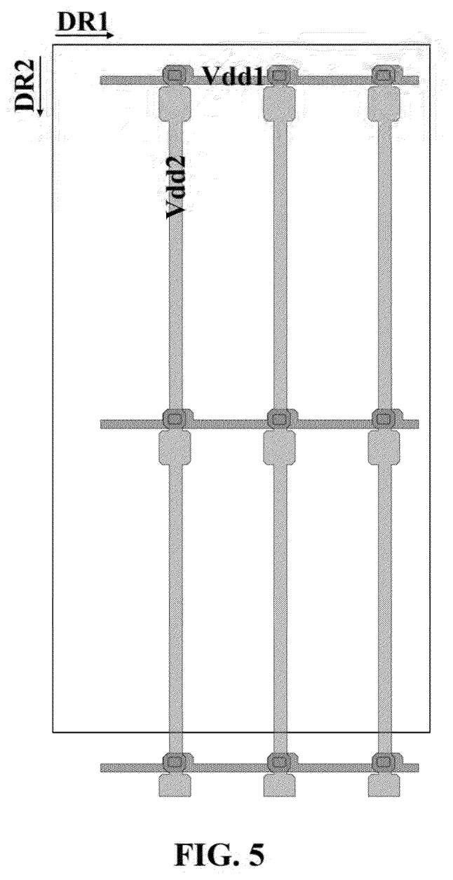

FIG. 5 is a diagram illustrating the structure of a first voltage supply network in a portion of an array substrate in some embodiments according to the present disclosure. Referring to FIG. 5, the first voltage supply network in some embodiments includes a plurality of first voltage supply lines Vdd1 and a plurality of third voltage supply lines Vdd2 interconnected to each other. Optionally, the plurality of first voltage supply lines Vdd1 extend along a direction substantially parallel to a first direction DR1. Optionally, the plurality of third voltage supply lines Vdd2 extend along a direction substantially parallel to a second direction DR2. Optionally, a respective first voltage supply line of the plurality of first voltage supply lines Vdd1 is connected to one or more third voltage supply lines of the plurality of third voltage supply lines Vdd2. Optionally, a respective third voltage supply line of the plurality of third voltage supply lines Vdd2 is connected to one or more first voltage supply lines of the plurality of first voltage supply lines Vdd1.

In one example, the plurality of first voltage supply lines Vdd1 are in the first signal line layer. Optionally, the plurality of third voltage supply lines Vdd2 are in the second signal line layer.

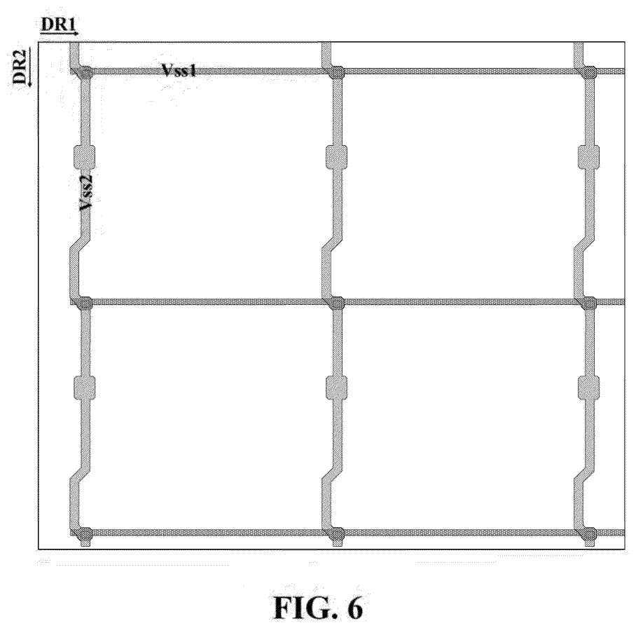

FIG. 6 is a diagram illustrating the structure of a second voltage supply network in a portion of an array substrate in some embodiments according to the present disclosure. Referring to FIG. 6, the second voltage supply network in some embodiments includes a plurality of second voltage supply lines Vss1 and a plurality of fourth voltage supply lines Vss2 interconnected to each other. Optionally, the plurality of second voltage supply lines Vss1 extend along a direction substantially parallel to a first direction DR1. Optionally, the plurality of fourth voltage supply lines Vss2 extend along a direction substantially parallel to a second direction DR2. Optionally, a respective second voltage supply line of the plurality of second voltage supply lines Vss1 is connected to one or more fourth voltage supply lines of the plurality of fourth voltage supply lines Vss2. Optionally, a respective fourth voltage supply line of the plurality of fourth voltage supply lines Vss2 is connected to one or more second voltage supply lines of the plurality of second voltage supply lines Vss1.

In one example, the plurality of second voltage supply lines Vss1 are in the first signal line layer. Optionally, the plurality of fourth voltage supply lines Vss2 are in the second signal line layer.

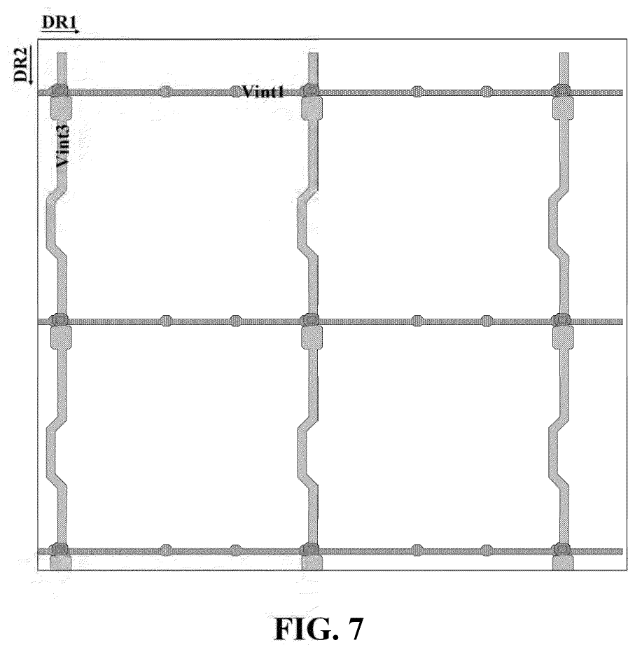

FIG. 7 is a diagram illustrating the structure of a first reset signal network in a portion of an array substrate in some embodiments according to the present disclosure. Referring to FIG. 7, the first reset signal network in some embodiments includes a plurality of first reset signal lines Vint1 and a plurality of third reset signal lines Vint3 interconnected to each other. Optionally, the plurality of first reset signal lines Vint1 extend along a direction substantially parallel to a first direction DR1. Optionally, the plurality of third reset signal lines Vint3 extend along a direction substantially parallel to a second direction DR2. Optionally, a respective first reset signal line of the plurality of first reset signal lines Vint1 is connected to one or more third reset signal lines of the plurality of third reset signal lines Vint3. Optionally, a respective third reset signal line of the plurality of third reset signal lines Vint3 is connected to one or more first reset signal lines of the plurality of first reset signal lines Vint1.

In one example, the plurality of first reset signal lines Vint1 are in the first signal line layer. Optionally, the plurality of third reset signal lines Vint3 are in the second signal line layer.

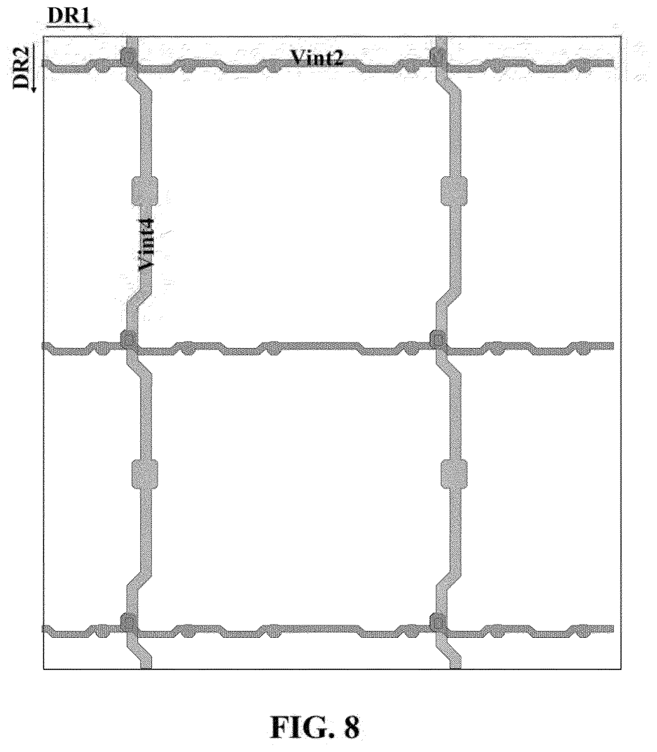

FIG. 8 is a diagram illustrating the structure of a second reset signal network in a portion of an array substrate in some embodiments according to the present disclosure.

Referring to FIG. 8, the second reset signal network in some embodiments includes a plurality of second reset signal lines Vint2 and a plurality of fourth reset signal lines Vint4 interconnected to each other. Optionally, the plurality of second reset signal lines Vint2 extend along a direction substantially parallel to a first direction DR1. Optionally, the plurality of fourth reset signal lines Vint4 extend along a direction substantially parallel to a second direction DR2. Optionally, a respective second reset signal line of the plurality of second reset signal lines Vint2 is connected to one or more fourth reset signal lines of the plurality of fourth reset signal lines Vint4. Optionally, a respective fourth reset signal line of the plurality of fourth reset signal lines Vint4 is connected to one or more second reset signal lines of the plurality of second reset signal lines Vint2.

In one example, the plurality of second reset signal lines Vint2 are in the first signal line layer. Optionally, the plurality of fourth reset signal lines Vint4 are in the second signal line layer.

Referring to FIG. 3A to FIG. 3L, in some embodiments, the pixel driving circuits of the array substrate are arranged in columns, including a (3k-2)-th column C(3k-2), a (3k-1)-th column C(3k-1), and a (3k)-th column C(3k) of K columns, K and k being positive integers, 1≤k≤(K/3).

As used herein, the terms “(3k-2)-th column”, “(3k-1)-th column”, and “(3k)-th column” are used in the context of the K columns. The array substrate may or may not include additional column(s) before the first column of the K columns and/or additional columns after the last column of the K columns. In the context of the array substrate, the term “(3k-1)-th column” does not necessarily denote an odd-numbered column, and the term “(3k-2)-th column” or “(3k)-th column” does not necessarily denote an even-numbered column. In one example, the (3k-2)-th column is an even-numbered column in the context of the K columns, but may be an odd-numbered column in the context of the array substrate. In another example, the (3k-2)-th column is an even-numbered column in the context of the K columns, and also an even-numbered column in the context of the array substrate. In one example, the (3k-1)-th column is an odd-numbered column in the context of the K columns, but may be an even-numbered column in the context of the array substrate. In another example, the (3k-1)-th column is an odd-numbered column in the context of the K columns, and also an odd-numbered column in the context of the array substrate. In one example, the (3k)-th column is an even-numbered column in the context of the K columns, but may be an odd-numbered column in the context of the array substrate. In another example, the (3k)-th column is an even-numbered column in the context of the K columns, and also an even-numbered column in the context of the array substrate.

In some embodiments, the (3k-2)-th column C(3k-2) includes a (3k-2)-th pixel driving circuit, the (3k-1)-th column C(3k-1) includes a (3k-1)-th pixel driving circuit, and the (3k)-th column C(3k) includes a (3k)-th pixel driving circuit. The (3k-2)-th pixel driving circuit, the (3k-1)-th pixel driving circuit, and the (3k)-th pixel driving circuit are in a same row.

In some embodiments, the (3k-2)-th column C(3k-2) includes a fourth voltage supply line of the plurality of fourth voltage supply lines Vss2; the (3k-1)-th column C(3k-1) includes a fourth reset signal line of the plurality of fourth reset signal lines Vint4; and the (3k)-th column C(3k) includes a third reset signal line of the plurality of third reset signal lines Vint3.

Optionally, the plurality of fourth voltage supply lines Vss2 are absent in the (3k-1)-th column C(3k-1) and absent in (3k)-th column C(3k).

Optionally, the plurality of fourth reset signal lines Vint4 are absent in the (3k-2)-th column C(3k-2) and absent in (3k)-th column C(3k).

Optionally, the plurality of third reset signal lines Vint3 are absent in the (3k-2)-th column C(3k-2) and absent in (3k-1)-th column C(3k-1).

In some embodiments, the (3k-2)-th column C(3k-2) of pixel driving circuits are configured to drive light emission of a (3k-2)-th column C(3k-2) of subpixels of a first color, the (3k)-th column C(3k) of pixel driving circuits are configured to drive light emission of a (3k)-th column C(3k) of subpixels of a second color, and the (3k-1)-th column C(3k-1) of pixel driving circuits are configured to drive light emission of a (3k-1)-th column C(3k-1) of subpixels of a third color. Optionally, the first color, the second color, and the third color are three different colors selected from a red color, a green color, and a blue color.

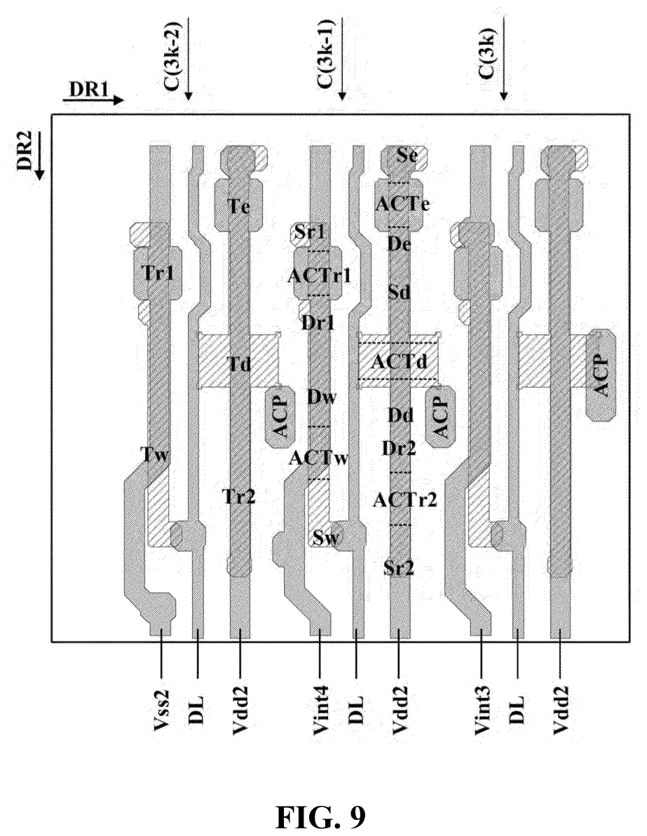

FIG. 9 is a diagram illustrating the structure of a semiconductor material layer and a second signal line layer in the portion of the array substrate depicted in FIG. 3A. In some embodiments, referring to FIG. 3A to FIG. 3K, and FIG. 9, an orthographic projection of a respective third voltage supply line of a plurality of third voltage supply lines Vdd2 on a base substrate substantially covers (e.g., at least 80% covers, at least 85% covers, at least 90% covers, at least 95% covers, at least 99% covers, or completely covers) an orthographic projection of an active layer ACTe of the light emitting control transistor Te in the respective pixel driving circuit on the base substrate, substantially covers (e.g., at least 80% covers, at least 85% covers, at least 90% covers, at least 95% covers, at least 99% covers, or completely covers) an orthographic projection of an active layer ACTr2 of the second reset transistor Tr2 on the base substrate, and at least partially overlaps with an orthographic projection of an active layer ACTd of the driving transistor Td on the base substrate. The inventors of the present disclosure discover that, by having this structure, the active layer ACTe of the light emitting control transistor Te, the active layer ACTr2 of the second reset transistor Tr2, and the active layer ACTd of the driving transistor Td can be protected from irradiation and stabilized.

In some embodiments, the orthographic projection of a respective third voltage supply line of a plurality of third voltage supply lines Vdd2 on a base substrate substantially covers (e.g., at least 80% covers, at least 85% covers, at least 90% covers, at least 95% covers, at least 99% covers, or completely covers) an orthographic projection of a combination of an active layer ACTe, a first electrode Se, and a second electrode De of the light emitting control transistor Te in the respective pixel driving circuit on the base substrate; substantially covers (e.g., at least 80% covers, at least 85% covers, at least 90% covers, at least 95% covers, at least 99% covers, or completely covers) an orthographic projection of a combination of an active layer ACTr2, a first electrode Sr2, and a second electrode Dr2 of the second reset transistor Tr2 on the base substrate; substantially covers (e.g., at least 80% covers, at least 85% covers, at least 90% covers, at least 95% covers, at least 99% covers, or completely covers) an orthographic projection of a combination of a first electrode Sd and a second electrode Dd of the driving transistor Td on the base substrate; and at least partially overlaps with an orthographic projection of an active layer ACTd of the driving transistor Td on the base substrate.

In some embodiments, the active layer ACTd, the first electrode Sd, and the second electrode Dd of the driving transistor Td; the active layer ACTe, the first electrode Se, and the second electrode De of the light emitting control transistor Te; and the active layer ACTr2, the first electrode Sr2, and the second electrode Dr2 of the second reset transistor Tr2 are parts of a first unitary structure. Optionally, the first unitary structure extends along a direction substantially parallel to an extension direction of the respective third voltage supply line of a plurality of third voltage supply lines Vdd2.

In some embodiments, in a first column of pixel driving circuits, an orthographic projection of a respective fourth voltage supply line of the plurality of fourth voltage supply lines Vss2 on a base substrate substantially covers (e.g., at least 80% covers, at least 85% covers, at least 90% covers, at least 95% covers, at least 99% covers, or completely covers) an orthographic projection of an active layer ACTr1 of the first reset transistor Tr1 in a first respective pixel driving circuit in the first column of pixel driving circuits on the base substrate, and substantially covers (e.g., at least 80% covers, at least 85% covers, at least 90% covers, at least 95% covers, at least 99% covers, or completely covers) an orthographic projection of an active layer ACTw of the data write transistor Tw in the first respective pixel driving circuit in the first column of pixel driving circuits on the base substrate. The inventors of the present disclosure discover that, by having this structure, the active layer ACTr1 of the first reset transistor Tr1 and the active layer ACTw of the data write transistor Tw can be protected from irradiation and stabilized.

In some embodiments, in the first column of pixel driving circuits, the orthographic projection of a respective fourth voltage supply line of the plurality of fourth voltage supply lines Vss2 on a base substrate substantially covers (e.g., at least 80% covers, at least 85% covers, at least 90% covers, at least 95% covers, at least 99% covers, or completely covers) an orthographic projection of a combination of an active layer ACTr1, a first electrode Sr1, and a second electrode Dr1 of the first reset transistor Tr1 in a first respective pixel driving circuit in the first column of pixel driving circuits on the base substrate, and substantially covers (e.g., at least 80% covers, at least 85% covers, at least 90% covers, at least 95% covers, at least 99% covers, or completely covers) an orthographic projection of a combination of an active layer ACTw and a second electrode Dw of the data write transistor Tw in the first respective pixel driving circuit in the first column of pixel driving circuits on the base substrate.

In some embodiments, in the first column of pixel driving circuits, the active layer ACTw, the first electrode Sw, and the second electrode Dw of the data write transistor Tw and the active layer ACTr1, the first electrode Sr1, and the second electrode Dr1 of the first reset transistor Tr1 are parts of a second unitary structure in the first column of pixel driving circuits. Optionally, the second unitary structure in the first column of pixel driving circuits extends along a direction substantially parallel to an extension direction of the respective fourth voltage supply line of the plurality of fourth voltage supply lines Vss2.

In some embodiments, in a second column of pixel driving circuits, an orthographic projection of a respective fourth reset signal line of the plurality of fourth reset signal lines Vint4 on a base substrate substantially covers (e.g., at least 80% covers, at least 85% covers, at least 90% covers, at least 95% covers, at least 99% covers, or completely covers) an orthographic projection of an active layer ACTr1 of the first reset transistor Tr1 in a second respective pixel driving circuit in the second column of pixel driving circuits on the base substrate, and substantially covers (e.g., at least 80% covers, at least 85% covers, at least 90% covers, at least 95% covers, at least 99% covers, or completely covers) an orthographic projection of an active layer ACTw of the data write transistor Tw in the second respective pixel driving circuit in the second column of pixel driving circuits on the base substrate. The inventors of the present disclosure discover that, by having this structure, the active layer ACTr1 of the first reset transistor Tr1 and the active layer ACTw of the data write transistor Tw can be protected from irradiation and stabilized.

In some embodiments, in the second column of pixel driving circuits, the orthographic projection of a respective fourth reset signal line of the plurality of fourth reset signal lines Vint4 on a base substrate substantially covers (e.g., at least 80% covers, at least 85% covers, at least 90% covers, at least 95% covers, at least 99% covers, or completely covers) an orthographic projection of a combination of an active layer ACTr1, a first electrode Sr1, and a second electrode Dr1 of the first reset transistor Tr1 in a second respective pixel driving circuit in the second column of pixel driving circuits on the base substrate; and substantially covers (e.g., at least 80% covers, at least 85% covers, at least 90% covers, at least 95% covers, at least 99% covers, or completely covers) an orthographic projection of a combination of an active layer ACTw and a second electrode Dw of the data write transistor Tw in the second respective pixel driving circuit in the second column of pixel driving circuits on the base substrate.

In some embodiments, in the second column of pixel driving circuits, the active layer ACTw, the first electrode Sw, and the second electrode Dw of the data write transistor Tw and the active layer ACTr1, the first electrode Sr1, and the second electrode Dr1 of the first reset transistor Tr1 are parts of a second unitary structure in the second column of pixel driving circuits. Optionally, the second unitary structure in the second column of pixel driving circuits extends along a direction substantially parallel to an extension direction of the respective fourth reset signal line of the plurality of fourth reset signal lines Vint4.

In some embodiments, in a third column of pixel driving circuits, an orthographic projection of a respective third reset signal line of the plurality of third reset signal lines Vint3 on a base substrate substantially covers (e.g., at least 80% covers, at least 85% covers, at least 90% covers, at least 95% covers, at least 99% covers, or completely covers) an orthographic projection of an active layer ACTr1 of the first reset transistor Tr1 in a third respective pixel driving circuit in the third column of pixel driving circuits on the base substrate, and substantially covers (e.g., at least 80% covers, at least 85% covers, at least 90% covers, at least 95% covers, at least 99% covers, or completely covers) an orthographic projection of an active layer ACTw of the data write transistor Tw in the third respective pixel driving circuit in the third column of pixel driving circuits on the base substrate. The inventors of the present disclosure discover that, by having this structure, the active layer ACTr1 of the first reset transistor Tr1 and the active layer ACTw of the data write transistor Tw can be protected from irradiation and stabilized.

In some embodiments, in the third column of pixel driving circuits, the orthographic projection of a respective third reset signal line of the plurality of third reset signal lines Vint3 on a base substrate substantially covers (e.g., at least 80% covers, at least 85% covers, at least 90% covers, at least 95% covers, at least 99% covers, or completely covers) an orthographic projection of a combination of an active layer ACTr1, a first electrode Sr1, and a second electrode Dr1 of the first reset transistor Tr1 in a third respective pixel driving circuit in the third column of pixel driving circuits on the base substrate; and substantially covers (e.g., at least 80% covers, at least 85% covers, at least 90% covers, at least 95% covers, at least 99% covers, or completely covers) an orthographic projection of a combination of an active layer ACTw and a second electrode Dw of the data write transistor Tw in the third respective pixel driving circuit in the third column of pixel driving circuits on the base substrate.

In some embodiments, in the third column of pixel driving circuits, the active layer ACTw, the first electrode Sw, and the second electrode Dw of the data write transistor Tw and the active layer ACTr1, the first electrode Sr1, and the second electrode Dr1 of the first reset transistor Tr1 are parts of a second unitary structure in the third column of pixel driving circuits. Optionally, the second unitary structure in the third column of pixel driving circuits extends along a direction substantially parallel to an extension direction of the respective third reset signal line of the plurality of third reset signal lines Vint3.

In some embodiments, in the (3k-2)-th column C(3k-2) of pixel driving circuits, an orthographic projection of a respective fourth voltage supply line of the plurality of fourth voltage supply lines Vss2 on a base substrate substantially covers (e.g., at least 80% covers, at least 85% covers, at least 90% covers, at least 95% covers, at least 99% covers, or completely covers) an orthographic projection of an active layer ACTr1 of the first reset transistor Tr1 in a first respective pixel driving circuit in the (3k-2)-th column C(3k-2) of pixel driving circuits on the base substrate, and substantially covers (e.g., at least 80% covers, at least 85% covers, at least 90% covers, at least 95% covers, at least 99% covers, or completely covers) an orthographic projection of an active layer ACTw of the data write transistor Tw in the first respective pixel driving circuit in the (3k-2)-th column C(3k-2) of pixel driving circuits on the base substrate. The inventors of the present disclosure discover that, by having this structure, the active layer ACTr1 of the first reset transistor Tr1 and the active layer ACTw of the data write transistor Tw can be protected from irradiation and stabilized.

In some embodiments, in the (3k-2)-th column C(3k-2) of pixel driving circuits, the orthographic projection of a respective fourth voltage supply line of the plurality of fourth voltage supply lines Vss2 on a base substrate substantially covers (e.g., at least 80% covers, at least 85% covers, at least 90% covers, at least 95% covers, at least 99% covers, or completely covers) an orthographic projection of a combination of an active layer ACTr1, a first electrode Sr1, and a second electrode Dr1 of the first reset transistor Tr1 in a first respective pixel driving circuit in the (3k-2)-th column C(3k-2) of pixel driving circuits on the base substrate, and substantially covers (e.g., at least 80% covers, at least 85% covers, at least 90% covers, at least 95% covers, at least 99% covers, or completely covers) an orthographic projection of a combination of an active layer ACTw and a second electrode Dw of the data write transistor Tw in the first respective pixel driving circuit in the (3k-2)-th column C(3k-2) of pixel driving circuits on the base substrate.

In some embodiments, in the (3k-2)-th column C(3k-2) of pixel driving circuits, the active layer ACTw, the first electrode Sw, and the second electrode Dw of the data write transistor Tw and the active layer ACTr1, the first electrode Sr1, and the second electrode Dr1 of the first reset transistor Tr1 are parts of a second unitary structure in the (3k-2)-th column C(3k-2) of pixel driving circuits. Optionally, the second unitary structure in the (3k-2)-th column C(3k-2) of pixel driving circuits extends along a direction substantially parallel to an extension direction of the respective fourth voltage supply line of the plurality of fourth voltage supply lines Vss2.

In some embodiments, in the (3k-1)-th column C(3k-1) of pixel driving circuits, an orthographic projection of a respective fourth reset signal line of the plurality of fourth reset signal lines Vint4 on a base substrate substantially covers (e.g., at least 80% covers, at least 85% covers, at least 90% covers, at least 95% covers, at least 99% covers, or completely covers) an orthographic projection of an active layer ACTr1 of the first reset transistor Tr1 in a second respective pixel driving circuit in the (3k-1)-th column C(3k-1) of pixel driving circuits on the base substrate, and substantially covers (e.g., at least 80% covers, at least 85% covers, at least 90% covers, at least 95% covers, at least 99% covers, or completely covers) an orthographic projection of an active layer ACTw of the data write transistor Tw in the second respective pixel driving circuit in the (3k-1)-th column C(3k-1) of pixel driving circuits on the base substrate. The inventors of the present disclosure discover that, by having this structure, the active layer ACTr1 of the first reset transistor Tr1 and the active layer ACTw of the data write transistor Tw can be protected from irradiation and stabilized.

In some embodiments, in the (3k-1)-th column C(3k-1) of pixel driving circuits, the orthographic projection of a respective fourth reset signal line of the plurality of fourth reset signal lines Vint4 on a base substrate substantially covers (e.g., at least 80% covers, at least 85% covers, at least 90% covers, at least 95% covers, at least 99% covers, or completely covers) an orthographic projection of a combination of an active layer ACTr1, a first electrode Sr1, and a second electrode Dr1 of the first reset transistor Tr1 in a second respective pixel driving circuit in the (3k-1)-th column C(3k-1) of pixel driving circuits on the base substrate; and substantially covers (e.g., at least 80% covers, at least 85% covers, at least 90% covers, at least 95% covers, at least 99% covers, or completely covers) an orthographic projection of a combination of an active layer ACTw and a second electrode Dw of the data write transistor Tw in the second respective pixel driving circuit in the (3k-1)-th column C(3k-1) of pixel driving circuits on the base substrate.

In some embodiments, in the (3k-1)-th column C(3k-1) of pixel driving circuits, the active layer ACTw, the first electrode Sw, and the second electrode Dw of the data write transistor Tw and the active layer ACTr1, the first electrode Sr1, and the second electrode Dr1 of the first reset transistor Tr1 are parts of a second unitary structure in the (3k-1)-th column C(3k-1) of pixel driving circuits. Optionally, the second unitary structure in the (3k-1)-th column C(3k-1) of pixel driving circuits extends along a direction substantially parallel to an extension direction of the respective fourth reset signal line of the plurality of fourth reset signal lines Vint4.

In some embodiments, in the (3k)-th column C(3k) of pixel driving circuits, an orthographic projection of a respective third reset signal line of the plurality of third reset signal lines Vint3 on a base substrate substantially covers (e.g., at least 80% covers, at least 85% covers, at least 90% covers, at least 95% covers, at least 99% covers, or completely covers) an orthographic projection of an active layer ACTr1 of the first reset transistor Tr1 in a third respective pixel driving circuit in the (3k)-th column C(3k) of pixel driving circuits on the base substrate, and substantially covers (e.g., at least 80% covers, at least 85% covers, at least 90% covers, at least 95% covers, at least 99% covers, or completely covers) an orthographic projection of an active layer ACTw of the data write transistor Tw in the third respective pixel driving circuit in the (3k)-th column C(3k) of pixel driving circuits on the base substrate. The inventors of the present disclosure discover that, by having this structure, the active layer ACTr1 of the first reset transistor Tr1 and the active layer ACTw of the data write transistor Tw can be protected from irradiation and stabilized.

In some embodiments, in the (3k)-th column C(3k) of pixel driving circuits, the orthographic projection of a respective third reset signal line of the plurality of third reset signal lines Vint3 on a base substrate substantially covers (e.g., at least 80% covers, at least 85% covers, at least 90% covers, at least 95% covers, at least 99% covers, or completely covers) an orthographic projection of a combination of an active layer ACTr1, a first electrode Sr1, and a second electrode Dr1 of the first reset transistor Tr1 in a third respective pixel driving circuit in the (3k)-th column C(3k) of pixel driving circuits on the base substrate; and substantially covers (e.g., at least 80% covers, at least 85% covers, at least 90% covers, at least 95% covers, at least 99% covers, or completely covers) an orthographic projection of a combination of an active layer ACTw and a second electrode Dw of the data write transistor Tw in the third respective pixel driving circuit in the (3k)-th column C(3k) of pixel driving circuits on the base substrate.

In some embodiments, in the (3k)-th column C(3k) of pixel driving circuits, the active layer ACTw, the first electrode Sw, and the second electrode Dw of the data write transistor Tw and the active layer ACTr1, the first electrode Sr1, and the second electrode Dr1 of the first reset transistor Tr1 are parts of a second unitary structure in the (3k)-th column C(3k) of pixel driving circuits. Optionally, the second unitary structure in the (3k)-th column C(3k) of pixel driving circuits extends along a direction substantially parallel to an extension direction of the respective third reset signal line of the plurality of third reset signal lines Vint3.

In another aspect, the present invention provides a display apparatus, including the array substrate described herein or fabricated by a method described herein, and one or more integrated circuits connected to the array substrate. Examples of appropriate display apparatuses include, but are not limited to, an electronic paper, a mobile phone, a tablet computer, a television, a monitor, a notebook computer, a digital album, a GPS, etc. Optionally, the display apparatus is an organic light emitting diode display apparatus. Optionally, the display apparatus is a micro light emitting diode display apparatus. Optionally, the display apparatus is a mini light emitting diode display apparatus.

In another aspect, the present disclosure provides a method of fabricating an array substrate. In some embodiments, the method includes forming a plurality of pixel driving circuits. Optionally, forming a respective pixel driving circuit of the plurality of pixel driving circuits includes forming a driving transistor, forming a light shield, and forming a node connecting line. Optionally, an orthographic projection of the light shield on a base substrate substantially covers an orthographic projection of an active layer of the driving transistor on the base substrate. Optionally, the light shield is electrically connected to a gate electrode of the driving transistor through the node connecting line. Optionally, the light shield, the node connecting line, and the gate electrode of the driving transistor are formed in three different layers.

The foregoing description of the embodiments of the invention has been presented for purposes of illustration and description. It is not intended to be exhaustive or to limit the invention to the precise form or to exemplary embodiments disclosed. Accordingly, the foregoing description should be regarded as illustrative rather than restrictive. Obviously, many modifications and variations will be apparent to practitioners skilled in this art. The embodiments are chosen and described in order to explain the principles of the invention and its best mode practical application, thereby to enable persons skilled in the art to understand the invention for various embodiments and with various modifications as are suited to the particular use or implementation contemplated. It is intended that the scope of the invention be defined by the claims appended hereto and their equivalents in which all terms are meant in their broadest reasonable sense unless otherwise indicated. Therefore, the term “the invention”, “the present invention” or the like does not necessarily limit the claim scope to a specific embodiment, and the reference to exemplary embodiments of the invention does not imply a limitation on the invention, and no such limitation is to be inferred. The invention is limited only by the spirit and scope of the appended claims. Moreover, these claims may refer to use “first”, “second”, etc. following with noun or element. Such terms should be understood as a nomenclature and should not be construed as giving the limitation on the number of the elements modified by such nomenclature unless specific number has been given. Any advantages and benefits described may not apply to all embodiments of the invention. It should be appreciated that variations may be made in the embodiments described by persons skilled in the art without departing from the scope of the present invention as defined by the following claims. Moreover, no element and component in the present disclosure is intended to be dedicated to the public regardless of whether the element or component is explicitly recited in the following claims.

1. An array substrate, comprising a plurality of pixel driving circuits;
wherein a respective pixel driving circuit of the plurality of pixel driving circuits comprises a driving transistor, a light shield, and a node connecting line;
wherein an orthographic projection of the light shield on a base substrate substantially covers an orthographic projection of an active layer of the driving transistor on the base substrate;
the light shield is electrically connected to a gate electrode of the driving transistor through the node connecting line;
the light shield, the node connecting line, and the gate electrode of the driving transistor are in three different layers.

2. The array substrate of claim 1, wherein the respective pixel driving circuit further comprises a first reset transistor;
wherein the light shield is electrically connected to a second electrode of the first reset transistor through the node connecting line.

3. The array substrate of claim 1, wherein the respective pixel driving circuit further comprises a storage capacitor;
wherein the orthographic projection of the light shield on the base substrate substantially covers an orthographic projection of a gate electrode of the driving transistor on the base substrate, and substantially covers an orthographic projection of a second capacitor electrode of the storage capacitor on the base substrate.

4. The array substrate of claim 1, further comprising a plurality of third voltage supply lines;
wherein the respective pixel driving circuit further comprises a light emitting control transistor, and a second reset transistor;
an orthographic projection of a respective third voltage supply line of the plurality of third voltage supply lines on the base substrate substantially covers an orthographic projection of an active layer of the light emitting control transistor in the respective pixel driving circuit on the base substrate, substantially covers an orthographic projection of an active layer of the second reset transistor on the base substrate, and at least partially overlaps with the orthographic projection of the active layer of the driving transistor on the base substrate.

5. The array substrate of claim 4, wherein the orthographic projection of a respective third voltage supply line of the plurality of third voltage supply lines on the base substrate substantially covers an orthographic projection of a combination of an active layer, a first electrode, and a second electrode of the light emitting control transistor in the respective pixel driving circuit on the base substrate; substantially covers an orthographic projection of a combination of an active layer, a first electrode, and a second electrode of the second reset transistor on the base substrate; substantially covers an orthographic projection of a combination of a first electrode and a second electrode of the driving transistor on the base substrate; and at least partially overlaps with an orthographic projection of an active layer of the driving transistor on the base substrate.

6. The array substrate of claim 1, further comprising a plurality of fourth voltage supply lines;
wherein the respective pixel driving circuit further comprises a data write transistor and a first reset transistor;
in a first column of pixel driving circuits, an orthographic projection of a respective fourth voltage supply line of the plurality of fourth voltage supply lines on the base substrate substantially covers an orthographic projection of an active layer of the first reset transistor in a first respective pixel driving circuit in the first column of pixel driving circuits on the base substrate, and substantially covers an orthographic projection of an active layer of the data write transistor in the first respective pixel driving circuit in the first column of pixel driving circuits on the base substrate.

7. The array substrate of claim 6, wherein, in the first column of pixel driving circuits, the orthographic projection of a respective fourth voltage supply line of the plurality of fourth voltage supply lines on the base substrate substantially covers an orthographic projection of a combination of an active layer, a first electrode, and a second electrode of the first reset transistor in the first respective pixel driving circuit in the first column of pixel driving circuits on the base substrate, and substantially covers an orthographic projection of a combination of an active layer and a second electrode of the data write transistor in the first respective pixel driving circuit in the first column of pixel driving circuits on the base substrate.

8. The array substrate of claim 1, further comprising a plurality of fourth reset signal lines;
wherein the respective pixel driving circuit further comprises a data write transistor and a first reset transistor;
in a second column of pixel driving circuits, an orthographic projection of a respective fourth reset signal line of the plurality of fourth reset signal lines on the base substrate substantially covers an orthographic projection of an active layer of the first reset transistor in a second respective pixel driving circuit in the second column of pixel driving circuits on the base substrate, and substantially covers an orthographic projection of an active layer of the data write transistor in the second respective pixel driving circuit in the second column of pixel driving circuits on the base substrate.

9. The array substrate of claim 8, wherein, in the second column of pixel driving circuits, the orthographic projection of a respective fourth reset signal line of the plurality of fourth reset signal lines on the base substrate substantially covers an orthographic projection of a combination of an active layer, a first electrode, and a second electrode of the first reset transistor in the second respective pixel driving circuit in the second column of pixel driving circuits on the base substrate; and substantially covers an orthographic projection of a combination of an active layer and a second electrode of the data write transistor in the second respective pixel driving circuit in the second column of pixel driving circuits on the base substrate.

10. The array substrate of claim 1, further comprising a plurality of third reset signal lines;
wherein the respective pixel driving circuit further comprises a data write transistor and a first reset transistor;
in a third column of pixel driving circuits, an orthographic projection of a respective third reset signal line of the plurality of third reset signal lines on the base substrate substantially covers an orthographic projection of an active layer of the first reset transistor in a third respective pixel driving circuit in the third column of pixel driving circuits on the base substrate, and substantially covers an orthographic projection of an active layer of the data write transistor in the third respective pixel driving circuit in the third column of pixel driving circuits on the base substrate.

11. The array substrate of claim 10, wherein, in the third column of pixel driving circuits, the orthographic projection of a respective third reset signal line of the plurality of third reset signal lines on the base substrate substantially covers an orthographic projection of a combination of an active layer, a first electrode, and a second electrode of the first reset transistor in the third respective pixel driving circuit in the third column of pixel driving circuits on the base substrate; and substantially covers an orthographic projection of a combination of an active layer and a second electrode of the data write transistor in the third respective pixel driving circuit in the third column of pixel driving circuits on the base substrate.

12. The array substrate of claim 1, further comprising a plurality of fourth voltage supply lines;
wherein the respective pixel driving circuit further comprises a data write transistor and a first reset transistor;
pixel driving circuits of the array substrate are arranged in columns, including a (3k-2)-th column, a (3k-1)-th column, and a (3k)-th column of K columns, K and k being positive integers, 1≤k≤(K/3);
in the (3k-2)-th column of pixel driving circuits, an orthographic projection of a respective fourth voltage supply line of the plurality of fourth voltage supply lines on the base substrate substantially covers an orthographic projection of an active layer of the first reset transistor in a first respective pixel driving circuit in the (3k-2)-th column of pixel driving circuits on the base substrate, and substantially covers an orthographic projection of an active layer of the data write transistor in the first respective pixel driving circuit in the (3k-2)-th column of pixel driving circuits on the base substrate.

13. The array substrate of claim 1, further comprising a plurality of fourth reset signal lines;
wherein the respective pixel driving circuit further comprises a data write transistor and a first reset transistor;
pixel driving circuits of the array substrate are arranged in columns, including a (3k-2)-th column, a (3k-1)-th column, and a (3k)-th column of K columns, K and k being positive integers, 1≤k≤(K/3);
in the (3k-1)-th column of pixel driving circuits, an orthographic projection of a respective fourth reset signal line of the plurality of fourth reset signal lines on the base substrate substantially covers an orthographic projection of an active layer of the first reset transistor in a second respective pixel driving circuit in the (3k-1)-th column of pixel driving circuits on the base substrate, and substantially covers an orthographic projection of an active layer of the data write transistor in the second respective pixel driving circuit in the (3k-1)-th column of pixel driving circuits on the base substrate.

14. The array substrate of claim 1, further comprising a plurality of third reset signal lines;
wherein the respective pixel driving circuit further comprises a data write transistor and a first reset transistor;
pixel driving circuits of the array substrate are arranged in columns, including a (3k-2)-th column, a (3k-1)-th column, and a (3k)-th column of K columns, K and k being positive integers, 1≤k≤(K/3);
in the (3k)-th column of pixel driving circuits, an orthographic projection of a respective third reset signal line of the plurality of third reset signal lines on the base substrate substantially covers an orthographic projection of an active layer of the first reset transistor in a third respective pixel driving circuit in the (3k)-th column of pixel driving circuits on the base substrate, and substantially covers an orthographic projection of an active layer of the data write transistor in the third respective pixel driving circuit in the (3k)-th column of pixel driving circuits on the base substrate.

15. The array substrate of claim 1, further comprising a plurality of fourth voltage supply lines, a plurality of fourth reset signal lines, and a plurality of third reset signal lines in a same layer;
wherein pixel driving circuits of the array substrate are arranged in columns, including a (3k-2)-th column, a (3k-1)-th column, and a (3k)-th column of K columns, K and k being positive integers, 1≤k≤(K/3);
the (3k-2)-th column comprises a fourth voltage supply line of the plurality of fourth voltage supply lines;
the (3k-1)-th column comprises a fourth reset signal line of the plurality of fourth reset signal lines; and
the (3k)-th column comprises a third reset signal line of the plurality of third reset signal lines.

16. The array substrate of claim 15, wherein the plurality of fourth voltage supply lines are absent in the (3k-1)-th column and absent in the (3k)-th column;
the plurality of fourth reset signal lines are absent in the (3k-2)-th column and absent in the (3k)-th column; and
the plurality of third reset signal lines are absent in the (3k-2)-th column and absent in the (3k-1)-th column.

17. The array substrate of claim 1, further comprising a first voltage supply network and a second voltage supply network;
wherein the first voltage supply network comprises a plurality of first voltage supply lines and a plurality of third voltage supply lines interconnected to each other;
the plurality of first voltage supply lines extend along a direction substantially parallel to a first direction;
the plurality of third voltage supply lines extend along a direction substantially parallel to a second direction;
a respective first voltage supply line of the plurality of first voltage supply lines is connected to one or more third voltage supply lines of the plurality of third voltage supply lines;
a respective third voltage supply line of the plurality of third voltage supply lines is connected to one or more first voltage supply lines of the plurality of first voltage supply lines; and
wherein the second voltage supply network comprises a plurality of second voltage supply lines and a plurality of fourth voltage supply lines interconnected to each other;
the plurality of second voltage supply lines extend along a direction substantially parallel to the first direction;
the plurality of fourth voltage supply lines extend along a direction substantially parallel to the second direction;
a respective second voltage supply line of the plurality of second voltage supply lines is connected to one or more fourth voltage supply lines of the plurality of fourth voltage supply lines; and
a respective fourth voltage supply line of the plurality of fourth voltage supply lines is connected to one or more second voltage supply lines of the plurality of second voltage supply lines;
wherein pixel driving circuits of the array substrate are arranged in columns, including a (3k-2)-th column, a (3k-1)-th column, and a (3k)-th column of K columns, K and k being positive integers, 1≤k≤(K/3);
the plurality of third voltage supply lines are present in the (3k-2)-th column, present in the (3k-1)-th column, and present in the (3k)-th column;
the plurality of fourth voltage supply lines are absent in the (3k-1)-th column and absent in the (3k)-th column.

18. The array substrate of claim 1, further comprising a first reset signal network;
wherein the first reset signal network comprises a plurality of first reset signal lines and a plurality of third reset signal lines interconnected to each other;
the plurality of first reset signal lines extend along a direction substantially parallel to a first direction;
the plurality of third reset signal lines extend along a direction substantially parallel to a second direction;
a respective first reset signal line of the plurality of first reset signal lines is connected to one or more third reset signal lines of the plurality of third reset signal lines; and
a respective third reset signal line of the plurality of third reset signal lines is connected to one or more first reset signal lines of the plurality of first reset signal lines;
wherein pixel driving circuits of the array substrate are arranged in columns, including a (3k-2)-th column, a (3k-1)-th column, and a (3k)-th column of K columns, K and k being positive integers, 1≤k≤(K/3); and
the plurality of third reset signal lines are absent in the (3k-2)-th column and absent in the (3k-1)-th column.

19. The array substrate of claim 1, further comprising a second reset signal network;
wherein the second reset signal network comprises a plurality of second reset signal lines and a plurality of fourth reset signal lines interconnected to each other;
the plurality of second reset signal lines extend along a direction substantially parallel to a first direction;
the plurality of fourth reset signal lines extend along a direction substantially parallel to a second direction;
a respective second reset signal line of the plurality of second reset signal lines is connected to one or more fourth reset signal lines of the plurality of fourth reset signal lines; and
a respective fourth reset signal line of the plurality of fourth reset signal lines is connected to one or more second reset signal lines of the plurality of second reset signal lines;
wherein pixel driving circuits of the array substrate are arranged in columns, including a (3k-2)-th column, a (3k-1)-th column, and a (3k)-th column of K columns, K and k being positive integers, 1≤k≤(K/3); and
the plurality of fourth reset signal lines are absent in the (3k-2)-th column and absent in the (3k)-th column.

20. A display apparatus, comprising the array substrate of claim 1, and one or more integrated circuits connected to the array substrate.
